(19) United States
(12) Patent Application Publication
(10) Pub. No.: US 2011/0001745 A1
(43) Pub. Date: Jan. 6, 2011

(54) CAPACITIVE LOAD DRIVE DEVICE, PLASMA DISPLAY DEVICE WITH A CAPACITIVE LOAD DRIVE DEVICE, AND DRIVE METHOD FOR A PLASMA DISPLAY PANEL

(75) Inventor: Toshikazu Nagaki, Osaka (JP)

Correspondence Address: GREENBLUM & BERNSTEIN, P.L.C., 1950 ROLAND CLARKE PLACE, RESTON, VA, 20191, US

(73) Assignee: PANASONIC CORPORATION, Osaka (JP)

(21) Appl. No.: 12/866,329

(22) PCT Filed: Feb. 5, 2009
(86) PCT No.: PCT/JP2009/000441

§ 371 Date: Aug. 5, 2010

(30) Foreign Application Priority Data
Feb. 6, 2008 (JP) 2008-026666

(51) Int. Cl. G09G 5/00; G09G 3/28; H03K 3/00

(52) U.S. Cl. 345/212; 327/111; 345/60

(57) ABSTRACT

The invention reduces power consumption, reduces EMI, and produces a stable sustain discharge. The sustain pulse generating circuit includes a power recovery circuit, clamping circuit, and auxiliary circuit. The power recovery circuit has a recovery inductor for LC resonance and a recovery capacitor for power recovery, recovers power stored in the capacitive load of the display electrode pairs to the recovery capacitor by LC resonance, and reuses the recovered power to drive the display electrode pairs. A clamping circuit clamps the display electrode pairs to the supply potential and the ground potential. An auxiliary circuit has an auxiliary capacitor connected in series with the recovery capacitor, and an auxiliary inductor that is used for LC resonance with the auxiliary capacitor, and increases the current flowing to the recovery inductor at the sustain pulse rise and fall to greater than the current that flows only as a result of the LC resonance of the recovery inductor and the capacitive load.

### TECHNICAL FIELD

The present invention relates to a device for driving a capacitive load, and relates more particularly to a capacitive load drive device for applying a pulse voltage to a plasma display panel, a plasma display device having this capacitive load drive device, and a method of driving a plasma display panel.

### RELATED ART

AC-driven surface discharge panels, of which the plasma display panel (PDP, also referred to as simply “panel” herein) is typical, has numerous discharge cells formed between opposing front and rear plates. A plurality of display electrode pairs each including a scan electrode and a sustain electrode are formed mutually parallel on the front plate glass, and a dielectric layer and protective layer are formed covering these display electrode pairs. A plurality of parallel data electrodes are formed on the rear plate glass and are covered by a dielectric layer. A plurality of ribs parallel to the data electrodes are formed on the dielectric layer, and a phosphor layer is formed on the surface of the dielectric layer and the sides of the ribs. So that the display electrode pairs and the data electrodes intersect three-dimensionally, the front plate and rear plate are disposed in opposition and sealed, and the discharge spaces formed inside are charged with a discharge gas including xenon at 5% partial pressure, for example. Discharge cells are formed in these discharge spaces between the display electrode pairs and the data electrodes. Ultraviolet light is produced by gas discharge inside the discharge cells in such a panel, and a color display is achieved by exciting and causing red (R), green (G), and blue (B) phosphors to emit by means of this UV light.

A common method of driving the panel is the subfield method, which is a method of presenting a gray scale display by dividing one field period into a plurality of subfields and then combining the output of the separately driven subfields.

Each subfield has an initialization period, an address period, and a sustain period. An initialization discharge is produced in the initialization period to form the wall charge necessary for the subsequent address operation on each electrode, and produce a priming particle (discharge initiator=excited particle) for producing a stable address discharge. In the address period an address pulse voltage is selectively applied to the discharge cell that is to display, producing an address discharge and forming a wall charge (this operation is also called “writing” below). In the sustain period, a sustain pulse voltage is alternately applied to the display electrode pairs including a scan electrode and a sustain electrode, producing a sustain discharge in the discharge cells that produced an address discharge, causing the phosphor layers in the corresponding discharge cells to emit and display an image.

Various power consumption reduction technologies have been proposed to reduce the power consumption of plasma display devices that use such panels. One technology for reducing power consumption in the sustain period focuses on each display electrode pair being a capacitive load with capacitance between the electrodes of each display electrode pair. This technology uses a resonant circuit having an inductor, causes the inductor and the interelectrode capacitance to resonate, recovers the charge stored in the interelectrode capacitance to a power recovery capacitor, and reuses the recovered charge to drive the display electrode pairs. This technology describes a power recovery circuit, and is taught, for example, in Japanese Unexamined Patent Appl. Pub. JP-A-S63-101897.

Japanese Unexamined Patent Appl. Pub. JP-A-2006-10750 teaches technology for reducing switching loss accompanying power recovery using an auxiliary resonance unit and improving recovery efficiency.

Japanese Unexamined Patent Appl. Pub. JP-A-2006-171765 teaches technology that uses a first resonance unit and a second resonance unit to accelerate the voltage rise of the sustain pulse while improving power recovery efficiency.

### DISCLOSURE OF THE INVENTION

### Problems to be Solved by the Invention

As panel resolution has increased, the number of electrodes that must be written in one subfield period has risen and the time required for one address period has increased accordingly. This has required, for example, shortening the sustain pulse period and shortening the sustain period.

However, in order to produce a stable sustain discharge, the period that the sustain pulse is held at the power supply voltage (the clamping period) must also be sufficient. In order to assure a sufficient clamping period while shortening the sustain pulse period, measures such as shortening the rise and fall times so that the sustain pulse has a sharp rise and fall must be used.

However, if the LC resonance period of the power recovery circuit is shortened in order to obtain a sufficiently sharp rising and falling edge characteristic in the sustain pulse, the maximum current (also called the peak current) flow when driving the electrodes rises. In addition to increasing the amount of reactive power that is consumed ineffectively without contributing to emission, this current rise also increases electromagnetic interference (EMI).

Reactive power can be decreased and EMI can be reduced by increasing the LC resonance period so that the rising edge of the sustain pulse is more gradual and peak current is suppressed, but the sustain pulse period increases as the slope of the rising edge of the sustain pulse decreases and the sustain period increases accordingly.

### Means for Solving the Problems

The present invention is directed to solving the foregoing problem, and a capacitive load drive device, a plasma display panel using the same, and a plasma display panel drive method according to the present invention can produce a sustain discharge that reduces power consumption and reduces EMI even as panel resolution increases.

A first aspect of the invention is a capacitive load drive device that has a sustain pulse generating circuit that applies a sustain pulse to a capacitive load and includes a power recovery circuit that has a recovery inductor for LC resonance and a recovery capacitor for power recovery, recovers power stored in the capacitive load into the recovery capacitor by means of LC resonance, and reuses the recovered power to drive the capacitive load, a clamping circuit that clamps the capacitive load to the supply potential and the ground potential, and an auxiliary circuit that has an auxiliary capacitor connected in series with the recovery capacitor, and an auxiliary inductor that is used for LC resonance with the auxiliary capacitor; the auxiliary circuit setting the potential of the auxiliary capacitor to a higher potential than the recovery capacitor immediately before the sustain pulse rise, and to a lower potential than the recovery capacitor immediately before the sustain pulse fall, by means of LC resonance of the auxiliary capacitor and the auxiliary inductor, and temporarily increasing the current flowing to the recovery inductor at the sustain pulse rise and fall to greater than the current that flows only as a result of the LC resonance of the recovery inductor and the capacitive load.

Because the current flowing to the power recovery circuit when the sustain pulse rises and falls can be temporarily increased in this aspect of the invention, the LC resonance period (referred to below as simply “resonance period”) of the recovery inductor and capacitive load can be increased, peak current can be reduced, power consumption can be reduced, and EMI can be reduced.

The foregoing capacitive load is preferably a plasma display panel (PDP).

A plasma display panel according to another aspect of the invention is a plasma display device that has a sustain pulse generating circuit that alternately applies a sustain pulse in the sustain period of a subfield having an initialization period, an address period, and a sustain period to display electrode pairs of a plasma display panel that has a plurality of scan electrodes and sustain electrodes rendering the display electrode pairs. The sustain pulse generating circuit includes a power recovery circuit that has a recovery inductor for LC resonance and a recovery capacitor for power recovery, recovers power stored in a capacitive load of the display electrode pairs into the recovery capacitor by means of LC resonance, and reuses the recovered power to drive the display electrode pairs, a clamping circuit that clamps the display electrode pairs to the supply potential and the ground potential, and an auxiliary circuit that has an auxiliary capacitor connected in series with the recovery capacitor, and an auxiliary inductor that is used for LC resonance with the auxiliary capacitor. The auxiliary circuit sets the potential of the auxiliary capacitor to a higher potential than the recovery capacitor immediately before the sustain pulse rise, and to a lower potential than the recovery capacitor immediately before the sustain pulse fall, by means of LC resonance of the auxiliary capacitor and the auxiliary inductor, and temporarily increases the current flowing to the recovery inductor at the sustain pulse rise and fall to more than the current that flows only as a result of LC resonance of the recovery inductor and the capacitive load.

Because the current flowing to the power recovery circuit when the sustain pulse rises and falls can be temporarily increased in this aspect of the invention, the LC resonance period (referred to below as simply “resonance period”) of the recovery inductor and capacitive load can be increased, peak current can be reduced, power consumption can be reduced, and EMI can be reduced.

In a plasma display device according to another aspect of the invention, the auxiliary circuit includes a power supply side auxiliary switch that has one terminal electrically connected to the supply potential and the other terminal electrically connected to the auxiliary inductor, and conducts when increasing the potential of the auxiliary capacitor, a reference potential side auxiliary switch that has one terminal electrically connected to the reference potential and the other terminal electrically connected to the auxiliary inductor, and conducts when lowering the potential of the auxiliary capacitor, a first diode that prevents backflow of current flowing forward from the auxiliary capacitor to the recovery inductor when the sustain pulse rises, and a second diode that prevents backflow of current flowing forward from the recovery inductor to the auxiliary capacitor when the sustain pulse falls.

As a result, by energizing the power supply side auxiliary switch immediately before the sustain pulse rises, and energizing the reference potential side auxiliary switch immediately before the sustain pulse falls, the current flowing to the power recovery circuit can be temporarily increased when raising and lowering the sustain pulse.

In a plasma display device according to another aspect of the invention, the auxiliary circuit sets the capacitance of the auxiliary capacitor to 1/10 of the capacitance of the recovery capacitor or less. As a result, the current flowing to the recovery inductor during the sustain pulse rising and falling can be increased, for a short period of time, to a level greater than the current caused only by the LC resonance of the recovery inductor and capacitive load.

Further preferably in a plasma display device according to another aspect of the invention, the auxiliary circuit sets the capacitance of the auxiliary capacitor and the inductance of the auxiliary inductor so that ½ the resonance period of the auxiliary capacitor and the auxiliary inductor is less than the period that the display electrode pairs are clamped to the supply potential and less than the period the display electrode pairs are clamped to the ground potential when the sustain pulse is produced.

As a result, charging from the power source to the auxiliary capacitor and discharging from the auxiliary capacitor to the reference potential can be accomplished within the period the display electrode pairs are clamped to the supply potential and within the period the display electrode pairs are clamped to the ground potential when generating sustain pulses.

In a plasma display device according to another aspect of the invention, the auxiliary circuit renders the auxiliary inductor by means of a first auxiliary inductor that is used when current flows from the supply potential side to the auxiliary capacitor, and a second auxiliary inductor that is used when current flows from the auxiliary capacitor to the reference potential side, and is configured with the other terminal of the power supply side auxiliary switch electrically connected to the first auxiliary inductor, and the other terminal of the reference potential side auxiliary switch electrically connected to the second auxiliary inductor.

As a result, the resonance period can be set differently when the potential of the auxiliary capacitor is set to a higher potential than the recovery capacitor and when it is set to a lower potential than the recovery capacitor.

In a plasma display device according to another aspect of the invention, the auxiliary circuit renders the auxiliary capacitor by means of a power supply side auxiliary capacitor that is used when setting a higher potential than the recovery capacitor and a reference potential side auxiliary capacitor that is used when setting a lower potential than the recovery capacitor, and uses the first auxiliary inductor for LC resonance with the power supply side auxiliary capacitor, and uses the second auxiliary inductor for LC resonance with the reference potential side auxiliary capacitor.

As a result, the resonance period can be set differently when the potential of the auxiliary capacitor is set to a higher potential than the recovery capacitor and when it is set to a lower potential than the recovery capacitor, and the lengths of the periods that the current flowing to the recovery inductor is increased above the current flow resulting only from the LC resonance of the recovery inductor and capacitive load can be set differently.

In a plasma display device according to another aspect of the invention, the auxiliary circuit connects a third auxiliary inductor separately from the first auxiliary inductor in series with the power supply side auxiliary capacitor, and connects a fourth auxiliary inductor separately from the second auxiliary inductor in series with the reference potential side auxiliary capacitor.

As a result, the auxiliary capacitor potential can be set to an even higher potential when set to a higher potential than the recovery capacitor, and can be set to an even lower potential when the auxiliary capacitor potential is set to a lower potential than the recovery capacitor.

In a plasma display device according to another aspect of the invention, the auxiliary circuit has two switching devices disposed in series between the supply potential and the reference potential with an electrical connection point electrically connected to the auxiliary capacitor, and a switching device inserted between the recovery capacitor and the auxiliary capacitor.

As a result, the auxiliary capacitor potential can be set to an even higher potential when set to a higher potential than the recovery capacitor, and can be set to an even lower potential when the auxiliary capacitor potential is set to a lower potential than the recovery capacitor.

In a plasma display device according to another aspect of the invention, the auxiliary circuit has a plurality of capacitors connected in series rendering the auxiliary capacitor, and the same number of auxiliary inductors, power supply side auxiliary switches, and reference potential side auxiliary switches as the number of plural capacitors rendering the auxiliary capacitance.

This aspect of the invention also enables setting the auxiliary capacitor potential to an even higher potential when set to a higher potential than the recovery capacitor, and setting the auxiliary capacitor potential to an even lower potential when set to a lower potential than the recovery capacitor.

In a plasma display device according to another aspect of the invention, the auxiliary circuit can vary the supply potential and reference potential used in the auxiliary circuit according to the display image.

This aspect of the invention enables changing the potential that is set when the potential of the auxiliary capacitor is set to a higher potential than the recovery capacitor, and the potential that is set when the potential of the auxiliary capacitor is set to a lower potential than the recovery capacitor, according to the display image. For example, when the brightness of the display image is high, the drive load of the display electrode pairs is greater than when the brightness of the display image is low, and stable drive is enabled by setting the potential of the auxiliary capacitor to an even higher potential when set to a higher potential than the recovery capacitor.

In a plasma display device according to another aspect of the invention, the auxiliary circuit can vary the energized time of the power supply side auxiliary switch and the reference potential side auxiliary switch according to the display image.

This aspect of the invention also enables changing the potential that is set when the potential of the auxiliary capacitor is set to a higher potential than the recovery capacitor, and the potential that is set when the potential of the auxiliary capacitor is set to a lower potential than the recovery capacitor, according to the display image.

Another aspect of the invention is a drive method for a plasma display panel that uses a power recovery circuit that has a recovery inductor for LC resonance and a recovery capacitor for power recovery, recovers power stored in a capacitive load of the display electrode pairs into the recovery capacitor by means of LC resonance, and reuses the recovered power to drive the display electrode pairs, a clamping circuit that clamps the display electrode pairs to the supply potential and the ground potential, and an auxiliary circuit that has an auxiliary capacitor connected in series with the recovery capacitor, and an auxiliary inductor that is used for LC resonance with the auxiliary capacitor, to drive a plasma display panel that has a plurality of scan electrodes and sustain electrodes rendering display electrode pairs by generating and alternately applying sustain pulses to the display electrode pairs in the sustain period of a plurality of subfields having an initialization period, address period, and sustain period. This plasma display panel drive method has includes steps of setting the potential of the auxiliary capacitor to a higher potential than the recovery capacitor immediately before the sustain pulse rise, and to a lower potential than the recovery capacitor immediately before the sustain pulse fall, and temporarily increasing the current flowing to the recovery inductor at the sustain pulse rise and fall to more than the current that flows only as a result of LC resonance of the recovery inductor and the capacitive load.

Because the current flowing to the power recovery circuit when the sustain pulse rises and falls can be temporarily increased in this aspect of the invention, the resonance period of the recovery inductor and capacitive load can be increased, peak current can be reduced, power consumption can be reduced, and EMI can be reduced.

In a drive method for a panel according to another aspect of the invention, a power supply side auxiliary switch having one terminal electrically connected to a supply potential and the other terminal electrically connected to the auxiliary inductor, and a reference potential side auxiliary switch having one terminal electrically connected to a reference potential and the other terminal electrically connected to the auxiliary inductor, are disposed to the auxiliary circuit; and the drive method energizes the power supply side auxiliary switch when increasing the potential of the auxiliary capacitor, and energizes the reference potential side auxiliary switch when lowering the potential of the auxiliary capacitor.

As a result, by energizing the power supply side auxiliary switch immediately before the sustain pulse rises, and energizing the reference potential side auxiliary switch immediately before the sustain pulse falls, the current flowing to the power recovery circuit can be temporarily increased when raising and lowering the sustain pulse.

In a drive method for a panel according to another aspect of the invention, the supply potential and reference potential used in the auxiliary circuit are controlled according to the display image.

This aspect of the invention enables changing the potential that is set when the potential of the auxiliary capacitor is set to a higher potential than the recovery capacitor, and the potential that is set when the potential of the auxiliary capacitor is set to a lower potential than the recovery capacitor, according to the display image.

In a drive method for a panel according to another aspect of the invention, the time that the power supply side auxiliary switch is energized when increasing the potential of the auxiliary capacitor, and the time that the reference potential side auxiliary switch is energized when lowering the potential of the auxiliary capacitor, are controlled according to the display image.

This aspect of the invention also enables changing the potential that is set when the potential of the auxiliary capacitor is set to a higher potential than the recovery capacitor, and the potential that is set when the potential of the auxiliary capacitor is set to a lower potential than the recovery capacitor, according to the display image.

Another aspect of the invention is a capacitive load drive device including a sustain pulse generating circuit that applies a sustain pulse to a capacitive load, and has a power recovery circuit that includes a recovery inductor for LC resonance, a recovery capacitor for power recovery, a power recovery path, and a power supply path, recovers power accumulated in the capacitive load through the power recovery path to the recovery capacitor by means of LC resonance, and reuses the recovered power to drive the capacitive load through the power supply path, and an auxiliary circuit including an auxiliary capacitor connected in series with the recovery capacitor, an auxiliary inductor used for LC resonance with the auxiliary capacitor, a first charging path that charges the auxiliary capacitor in a first direction, and a second charging path that charges the auxiliary capacitor in a second direction. The auxiliary circuit charges the auxiliary capacitor in the first direction immediately before driving the capacitive load through the power supply path, charges the auxiliary capacitor in the second direction immediately before recovering power through the power recovery path to the recovery capacitor, sets the potential of the auxiliary capacitor to a higher potential than the recovery capacitor immediately before the sustain pulse rise, and to a lower potential than the recovery capacitor immediately before the sustain pulse fall, by means of LC resonance of the auxiliary capacitor and the auxiliary inductor, and temporarily increases the current flowing to the recovery inductor at the sustain pulse rise and fall to greater than the current that flows only as a result of the LC resonance of the recovery inductor and the capacitive load.

A capacitive load drive device according to another aspect of the invention is a capacitive load drive device that drives a capacitive load using primary power and auxiliary power, and includes a primary capacitance unit that can store and discharge the primary power; an auxiliary storage unit that can store and discharge auxiliary power; a primary inductance unit that produces a first LC resonance with the capacitive load; a recovery path representing a path for recovering the primary power from the capacitive load through the primary inductance unit to the primary capacitance unit based on the first LC resonance; a supply path representing a path for supplying the recovered primary power from the primary capacitance unit through the primary inductance unit to the capacitive load based on the first LC resonance; a recovery charge path that includes the auxiliary storage unit and represents a path for charging the auxiliary power to the auxiliary storage unit in a direction strengthening the primary power recovery operation; a recovery discharge path representing a path for discharging the auxiliary power charged to the auxiliary storage unit from the primary inductance unit to the auxiliary storage unit, and accelerating the primary power recovery operation; a supply charge path that includes the auxiliary storage unit, and represents a path for charging the auxiliary power to the auxiliary storage unit in a direction strengthening the primary power supply operation; and a supply discharge path representing a path for discharging the auxiliary power charged to the auxiliary storage unit from the auxiliary storage unit to the primary inductance unit, and accelerating the primary power supply operation. The recovery path shares at least part of the recovery discharge path, and the supply path shares at least part of the supply discharge path.

A capacitive load drive device according to another aspect of the invention is a capacitive load drive device that drives a capacitive load using a first power source and a second power source, including: a sustain circuit that supplies primary power from the first power source to a capacitive load, and holds a specific electrode of the capacitive load to a primary potential and reference potential; a power feedback circuit that recovers primary power from the capacitive load while the sustain potential held in the sustain circuit changes from a primary potential to a reference potential, and while the sustain potential changes from the reference potential to the primary potential supplies the recovered primary power to the capacitive load; and an auxiliary circuit that receives part of the primary power from the power feedback circuit as auxiliary power, and receives auxiliary power from the second power source. The power feedback circuit accelerates the primary power recovery operation and supply operation based on the auxiliary power received by the auxiliary circuit.

Another aspect of the invention is a plasma display device that uses the capacitive load drive device described above.

Another aspect of the invention is a drive method for a plasma display panel that drive method for a plasma display panel that drives a capacitive load using a first power source and a second power source, including: a step of supplying primary power from the first power source to a capacitive load, and holding a specific electrode of the capacitive load to a primary potential and reference potential; a step of recovering primary power from the capacitive load while the held sustain potential changes from a primary potential to a reference potential, and supplying the recovered primary power to the capacitive load while the sustain potential changes from the reference potential to the primary potential; and a step of receiving part of the primary power as auxiliary power, and receiving auxiliary power from the second power source; wherein the recovery and supply steps accelerate the primary power recovery operation and supply operation by using the received auxiliary power.

### EFFECT OF THE INVENTION

By rendering sustain pulses with a steeper edge characteristic, a capacitive load drive device, a plasma display device that uses the capacitive load drive device, and a drive method for a plasma display panel according to the present invention can produce stable sustain pulses by assuring a sufficient clamping period even as the sustain pulse period becomes shorter in conjunction with increased panel resolution, and can reduce power consumption and EMI by reducing peak current.

Other objects and attainments together with a fuller understanding of the invention will become apparent and appreciated by referring to the following description and claims taken in conjunction with the accompanying drawings.

### BRIEF DESCRIPTION OF THE DRAWINGS

FIG. 1 is an exploded oblique view showing the structure of a panel according to a first embodiment of the invention.

FIG. 2 is an electrode diagram for a panel according to a first embodiment of the invention.

FIG. 3 is a waveform diagram showing the drive voltage applied to each electrode in a panel according to a first embodiment of the invention.

FIG. 4 is a block diagram of a plasma display device in the first embodiment of the invention.

FIG. 5 is a block diagram of the sustain pulse generating circuit in the first embodiment of the invention.

FIG. 6 is a circuit diagram of the sustain pulse generating circuit in the first embodiment of the invention.

FIG. 7 is a timing chart describing the operation of the sustain pulse generating circuit in the first embodiment of the invention.

FIG. 8 is an enlarged view of the timing chart in the first embodiment of the invention.

FIG. 9 is a circuit diagram of the sustain pulse generating circuit in a second embodiment of the invention.

FIG. 10 is a circuit diagram of the sustain pulse generating circuit in a variation of the second embodiment of the invention.

FIG. 11 is a timing chart describing the operation of the sustain pulse generating circuit in a variation of the second embodiment of the invention.

FIG. 12 is an enlarged timing chart describing the operation of the sustain pulse generating circuit in a variation of the second embodiment of the invention.

FIG. 13 is a circuit diagram of the sustain pulse generating circuit in a third embodiment of the invention.

FIG. 14 is a timing chart describing the operation of the sustain pulse generating circuit in the third embodiment of the invention.

FIG. 15 is a circuit diagram of the sustain pulse generating circuit in a fourth embodiment of the invention.

FIG. 16 is a timing chart describing the operation of the sustain pulse generating circuit in the fourth embodiment of the invention.

FIG. 17 is a waveform diagram showing when the supply voltage of an auxiliary circuit is variable in another embodiment of the invention.

FIG. 18 is a waveform diagram showing when the energize time of a supply-side auxiliary switch is variable in another embodiment of the invention.

### KEYS TO THE REFERENCE NUMBERS

1 plasma display panel
10 panel
21 (glass) front panel
22 scan electrode
23 sustain electrode
24 display electrode pairs
25, 33 dielectric layer
26 protective layer
31 back plate
32 data electrode
34 barrier ribs
35 phosphor layer
41 image signal processing circuit
42 data electrode drive circuit
43 scan electrode drive circuit
44 sustain electrode drive circuit
45 timing signal generating circuit
50, 60, 501, 501A, 502, 503 sustain pulse generating circuit
51, 61 power recovery circuit
52, 62 clamping circuit
53, 63, 531, 531A, 532, 533 auxiliary circuit

### BEST MODE FOR CARRYING OUT THE INVENTION

Some preferred embodiments of the invention are described below with reference to the accompanying figures wherein parts having effectively the same configuration, operation, and effect are denoted by the same reference numerals or symbols. Numbers used in the following description are shown by way of example only to clearly describe the invention, and the invention is not limited to said numbers in any way. Switching states expressed as on and off are also used by way of example only to describe a specific embodiment of the invention, and it will be obvious that the same effect can be achieved using different combinations of switching states. Connections between specific elements and components are also shown by way of example only, and the connections achieving the function of the invention are not so limited.

### Embodiment 1

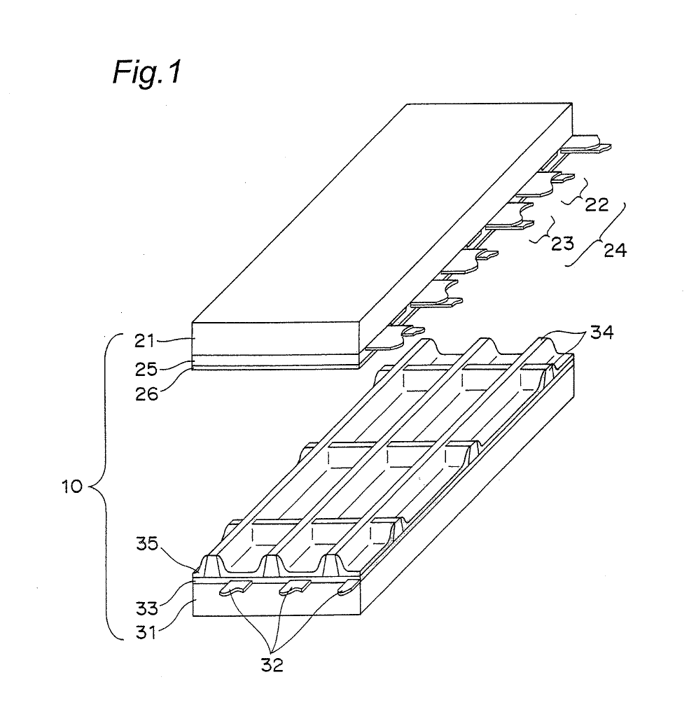

FIG. 1 is a partially exploded oblique view showing the structure of a panel 10 according to a first embodiment of the invention. A plurality of display electrode pairs 24 each composed of a scan electrode 22 and sustain electrode 23 pair are formed parallel to each other on a glass front plate 21. A dielectric layer 25 is formed covering the scan electrodes 22 and sustain electrodes 23, and a protective layer 26 is formed over the dielectric layer 25.

The protective layer 26 is made from a material consisting primarily of MgO (magnesium oxide). MgO has been proven for use as a panel material that lowers the discharge start voltage in the discharge cells, has a high secondary electron emission coefficient when the cells are filled with neon (Ne) and xenon (Xe), and has excellent durability.

A plurality of data electrodes 32 are formed parallel to each other on a back plate 31, a dielectric layer 33 is formed covering the data electrodes 32, and barrier ribs 34 are formed thereon in a grid-like pattern of wells. A phosphor layer 35 that emits red (R), green (G), and blue (B) is disposed on the sides of the barrier ribs 34 and the top of the dielectric layer 33.

The front plate 21 and back plate 31 are then placed together so that the display electrode pairs 24 and data electrodes 32 intersect three-dimensionally with small discharge spaces rendered therebetween, and the perimeter is then sealed with glass frit or other sealing material. A discharge gas of neon and xenon is then injected to the internal discharge space. In a first embodiment of the invention a discharge gas with a xenon partial pressure of approximately 10% is used to improve emission efficiency. The discharge space is segmented into a plurality of cells by the barrier ribs 34, and the discharge cells are formed where the display electrode pairs 24 and data electrodes 32 intersect. Gas discharge in each of the discharge cells produces ultraviolet (UV) light, and color images are displayed by using the UV light to excite the phosphors to emit R, G, and B as needed.

It should be noted that the structure of the panel 10 is not limited to the foregoing. For example, the barrier ribs may be rendered in a striped pattern. The mixture of the discharge gas is also not limited to the values described above, and other mix ratios may be used.

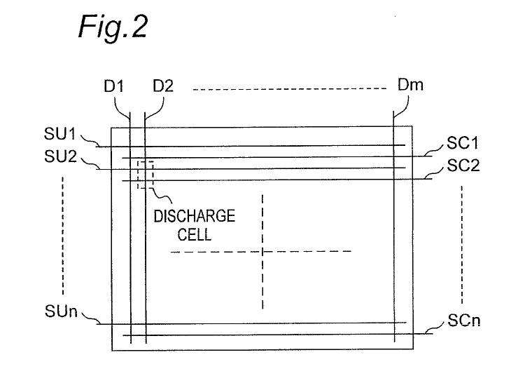

FIG. 2 shows the electrode arrangement of the panel 10. As shown in the figure, n scan electrodes SC1, SC2 . . . SCn (identical to scan electrodes 22 in FIG. 1, and identified below as scan electrodes SC1 to SCn) and n sustain electrodes SU1, SU2 . . . SUn (identical to sustain electrodes 23 in FIG. 1, and identified below as sustain electrodes SU1 to SUn) that are long in the row direction, and m data electrodes D1, D2 . . . Dm (identical to data electrodes 32 in FIG. 1, and identified below as data electrodes D1 to Dm) that are long in the column direction, are formed on the panel 10. A total of m×n discharge cells are thus formed in the discharge spaces where each scan electrode SCi (i=1 to n) and sustain electrode SUi pair intersects with one data electrode Dj (j=1 to m).

The drive voltage waveforms for driving the panel 10 and the operating concept thereof are described next. The plasma display device according to this embodiment of the invention uses the subfield method to display color gradations by dividing one field period into a plurality of subfields and controlling each discharge cell to emit or not emit in each subfield. Each subfield has an initialization period, an address period, and a sustain period.

A priming discharge is produced in the initialization period in order to form the wall charge required for the following address discharge on each electrode. This also works to produce priming particles (discharge initiator or excited particles) for reducing discharge delay and producing a stable address discharge. This initialization operation includes an all-cell initialization operation that produces the priming discharge in all discharge cells, and a selective initialization operation that selectively produces a priming discharge only in the discharge cells in which a sustain discharge was produced in the immediately preceding subfield.

In the address period, an address discharge is selectively produced in the discharge cells that are to emit in the following sustain period, forming a wall charge.

In the sustain period, sustain pulses are alternately applied in a number proportional to the luminance weight to the display electrode pairs 24, causing the discharge cells in which an address discharge was produced to produce a sustain discharge and thus emit. The proportional constant expressing the ratio between the sustain pulse count and the luminance weight is called the “luminance scaling factor.”

In the first embodiment of the invention, one field is composed of ten subfields SF1, SF2, . . . SF10, and the subfields are assigned a specific luminance weight such as 1, 2, 3, 6, 11, 18, 30, 44, 60, 80. The all-cell initialization operation is applied in the initialization period of subfield SF1, and the selective initialization operation is applied in the initialization period of subfields SF2 to SF10. As a result, discharge not related to image display occurs only as a result of the discharge in the all-cell initialization operation in subfield SF1. Because the black luminance representing the luminance in black display areas does not produce a sustain discharge and results only from the weak emission of the all-cell initialization operation, a high contrast image display is possible. In addition, in the sustain period of each subfield, a number of sustain pulses equal to the luminance weight of each subfield multiplied by a specific luminance scaling factor is applied to each display electrode pair 24.

However, in this first embodiment of the invention, the subfield count and the luminance weight of each subfield are not limited to the values described above, and the subfield configuration may be changed based on the image signal, for example.

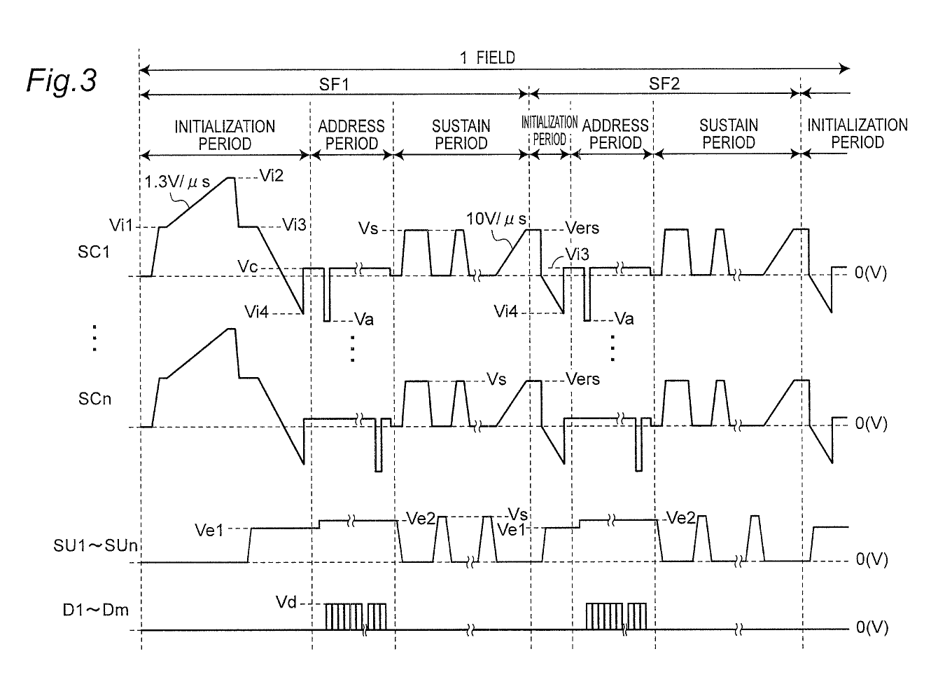

FIG. 3 is a waveform diagram of the drive voltages applied to the electrodes of the panel 10. The drive voltage waveform of two subfields, specifically a subfield to which the all-cell initialization operation is applied (“all-cell initialization subfields” below) and a subfield to which the selective initialization operation is applied (“selective initialization subfields” below) are shown in FIG. 3, but the drive voltage waveforms in the other subfields are substantially the same. Note also that the scan electrode SCi, sustain electrode SUi, and data electrode Dj below denote the electrodes selected from among all electrodes based on the image data.

Subfield SF1, which is an all-cell initialization subfield, is described first below.

In the first half of the initialization period in subfield SF1, 0 V is applied to data electrodes D1 to Dm and sustain electrodes SU1 to SUn, and an inclined waveform voltage (“ramp-up waveform voltage” below) that rises gradually from a positive voltage Vi1, which is less than or equal to the discharge start voltage applied to the sustain electrodes SU1 to SUn, to a positive voltage Vi2 exceeding the discharge start voltage is applied to scan electrodes SC1 to SCn.

While the ramp-up waveform voltage is rising, a weak initialization discharge is sustained between the scan electrodes SC1 to SCn and sustain electrodes SU1 to SUn and the data electrodes D1 to Dm. A negative wall voltage accumulates in the top part of the scan electrodes SC1 to SCn, and a positive wall voltage accumulates in the top part of the data electrodes D1 to Dm and the top part of the sustain electrodes SU1 to SUn. Note that a wall voltage in the top part of an electrode denotes a voltage produced by the wall charge accumulated on the dielectric layers covering the electrodes, the protective layer, and the phosphor layer.

In the second half of the initialization period, a positive voltage Ve1 is applied to sustain electrodes SU1 to SUn, 0 V is applied to data electrodes D1 to Dm, and an inclined waveform voltage (“ramp-down waveform voltage” below) that drops gradually from a positive voltage Vi3, which is less than or equal to the discharge start voltage applied to the sustain electrodes SU1 to SUn, to a negative voltage Vi4 greater than the discharge start voltage is applied to the scan electrodes SC1 to SCn. During this time a weak initialization discharge is sustained between the scan electrodes SC1 to SCn and sustain electrodes SU1 to SUn and the data electrodes D1 to Dm. The negative wall voltage in the top part of the scan electrodes SC1 to SCn and the positive wall voltage in the top part of the sustain electrodes SU1 to SUn weakens, and the positive wall voltage in the top part of the data electrodes D1 to Dm is adjusted to a value appropriate to the address operation.

This completes the all-cell initialization operation that produces an initialization discharge in all discharge cells.

Note that as shown in the initialization period for subfield SF2 in FIG. 3 a drive voltage waveform that omits the first half of the initialization period may be applied to each electrode. More specifically, a positive voltage Ve1 is applied to the sustain electrodes SU1 to SUn and 0 V is applied to data electrodes D1 to Dm, and a ramp-down waveform voltage that drops from a voltage (such as the ground potential) that is less than or equal to the discharge start voltage to a negative voltage Vi4 is applied to the scan electrodes SC1 to SCn. As a result, a weak initialization discharge is produced in the discharge cells where a sustain discharge was produced in the sustain period of the previous subfield, and the wall voltage of the top part of the scan electrode SCi and the top part of the sustain electrode SUi weakens. In the discharge cells where a sufficient positive wall voltage is accumulated in the top part of the data electrode Dj (j=1 to m) by the immediately preceding sustain discharge, the excessive part of this wall voltage is discharged and the wall voltage is adjusted to a wall voltage appropriate to the address operation. The discharge cells in which a sustain discharge was not produced in the previous subfield do not discharge, and the wall voltage is held at the wall voltage when the initialization period of the previous subfield ended. This initialization operation thus omitting the first half described above is the selective discharge operation producing an initial discharge in the discharge cells to which the sustain operation was applied in the sustain period of the immediately preceding subfield.

In the following address period positive voltage Ve2 is first applied to the sustain electrodes SU1 to SUn and a positive voltage Vc is applied to the scan electrodes SC1 to SCn.

A negative scan pulse voltage Va is then applied to the scan electrode SC1 of row 1 and a positive address pulse voltage Vd is applied to the data electrodes Dj (j=1 to m) selected from the group of data electrodes D1 to Dm of the discharge cells on row 1 that are to emit. The voltage difference on the data electrode Dj and on the scan electrode SC1 at the intersection thereof is the difference (Vd−Va) of the externally applied voltages and the difference between the wall voltage on the data electrode Dj and the wall voltage on the scan electrode SC1, and exceeds the discharge start voltage. As a result, a discharge is produced between the data electrode Dj and the scan electrode SC1.

In addition, because positive voltage Ve2 is applied to the sustain electrodes SU1 to SUn, the voltage difference on the sustain electrode SU1 and on the scan electrode SC1 is the difference (Ve2−Va) between the externally applied voltages and the difference between the wall voltage on the sustain electrode SU1 and the wall voltage on the scan electrode SC1. By setting voltage Ve2 at this time to a voltage slightly lower than the discharge start voltage, the space between the sustain electrode SU1 and the scan electrode SC1 can be primed to easily produce a discharge while not actually discharging. As a result, discharge produced between the data electrode Dj and the scan electrode SC1 can be used as a trigger to cause a discharge between the sustain electrode SU1 and the scan electrode SC1 in the area intersecting with the data electrode Dj. This causes an address discharge in the discharge cell that should emit, stores a positive wall voltage on the scan electrode SC1, a negative wall voltage on the sustain electrode SU1, and a negative wall voltage on the data electrode Dj.

An address operation that produces an address discharge in the discharge cells that are to emit on row 1, and accumulates a wall voltage on each electrode, is thus executed. However, because the voltage at the intersection of the scan electrode SC1 and the data electrodes D1 to Dm to which the address pulse voltage Vd was not applied does not exceed the discharge start voltage, an address discharge is not emitted. This address operation is repeated to the discharge cells on row n, and the address period then ends.

In the following sustain period a positive sustain pulse voltage Vs is first applied to the scan electrodes SC1 to SCn, and the ground potential, that is, 0 V, is applied to the sustain electrodes SU1 to SUn. As a result, the voltage difference between the scan electrode SC1 and the sustain electrode SU1 in the discharge cells where an address discharge was not produced is the sustain pulse voltage Vs plus the difference between the wall voltage on the scan electrode SCi and the wall voltage on the sustain electrode SUi, and exceeds the discharge start voltage.

A sustain discharge is thus produced between the scan electrode SCi and sustain electrode SUi, and the UV light produced at this time causes the phosphor layer 35 to emit. A negative wall voltage is thus stored on the scan electrode SCi and a positive wall voltage is stored on the sustain electrode SUi. A positive wall voltage is also stored on the data electrode Dj. A sustain discharge is not produced in the discharge cells where an address discharge does not occur in the address period, and the wall voltage at the end of the initialization period is sustained.

A reference potential of 0 V is then applied to the scan electrodes SC1 to SCn, and a positive sustain pulse voltage Vs is applied to the sustain electrodes SU1 to SUn. As a result, the voltage difference on the sustain electrode SUi and the scan electrode SCi exceeds the discharge start voltage in the discharge cells that produced a sustain discharge. As a result, a sustain discharge occurs between the sustain electrode SUi and scan electrode SCi again, a negative wall voltage is stored on the sustain electrode SUi, and a positive wall voltage is stored on the scan electrode SCi. Thereafter, a number of sustain pulses equal to the luminance weight multiplied by the luminance scale factor is alternately applied to the scan electrodes SC1 to SCn and sustain electrodes SU1 to SUn, thus writing a potential difference between the electrodes of the display electrode pairs 24. As a result, a sustain discharge is sustained in the discharge cells that produced an address discharge in the address period.

At the end of the sustain period, an inclined waveform voltage (“erase ramp waveform voltage” below) that rises gradually from the reference potential of 0 V toward a positive voltage Vers is applied to the scan electrodes SC1 to SCn. This causes a weak discharge to be sustained while erasing part or all of the wall voltages on the scan electrode SCi and sustain electrode SUi while leaving the positive wall voltage on the data electrode Dj.

More specifically, after the sustain electrodes SU1 to SUn return to 0 V, an erase ramp waveform voltage that rises from the reference potential of 0 V toward a positive voltage Vers that exceeds the discharge start voltage is generated and applied to the scan electrodes SC1 to SCn. A weak discharge is thus produced between the sustain electrode SUi and scan electrode SCi of the discharge cells that produced a sustain discharge. This weak discharge is sustained throughout the period in which the voltage applied to the scan electrodes SC1 to SCn rises.

The charged particles produced by this weak discharge are stored as a wall charge on the sustain electrode SUi and the scan electrode SCi in order to buffer the voltage difference between the sustain electrode SUi and scan electrode SCi. As a result, while the positive wall charge is left on the data electrode Dj, the wall voltages between the scan electrodes SC1 to SCn and sustain electrodes SU1 to SUn weaken to the difference between the voltage applied to the scan electrode SCi and the discharge start voltage, that is, to approximately voltage Vers minus the discharge start voltage. The last discharge in the sustain period produced by this erase ramp waveform voltage is referred to as the “erase discharge” below.

The operation in the next subfield is substantially identical to the operation described above except for the number of sustain pulses in the sustain period.

The foregoing summarizes the drive voltages applied to the electrodes of the panel 10 in this first embodiment of the invention.

In this first embodiment of the invention, the work of an auxiliary circuit described below cancels the peak current occurring when a sustain pulse is generated, and balances canceling reactive power and reducing EMI (electromagnetic interference) with achieving a stable sustain discharge. This operation is described in further detail below.

The configuration of a plasma display device according to the first embodiment of the invention is described next.

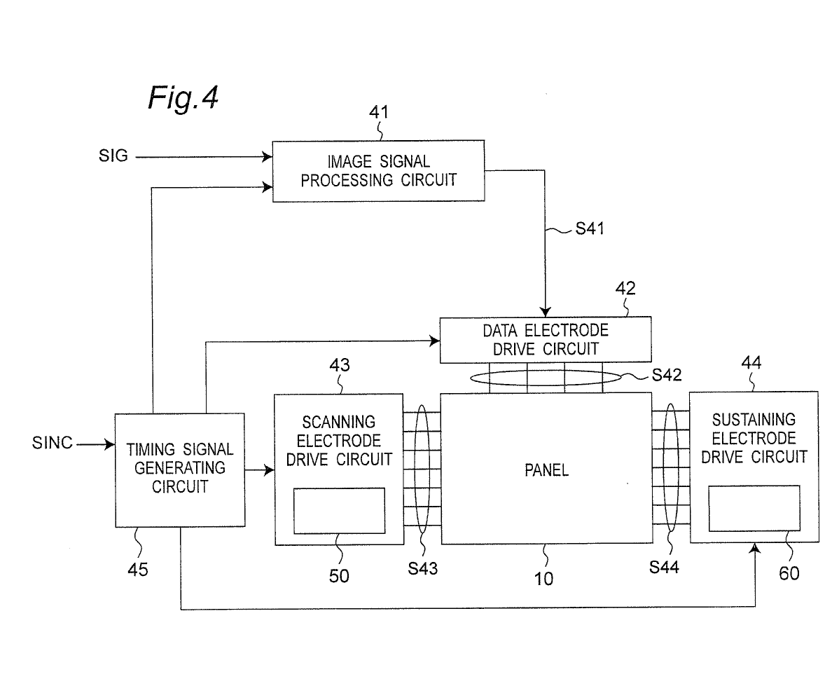

FIG. 4 is a block diagram of a plasma display device. As shown in FIG. 4 the plasma display device 1 has a panel 10, an image signal processing circuit 41, a data electrode drive circuit 42, a scan electrode drive circuit 43, a sustain electrode drive circuit 44, a timing signal generating circuit 45, and a power supply circuit (not shown in the figure) that supplies the necessary power to the other circuit blocks.

The image signal processing circuit 41 converts the input image signal SIG to image data S41 describing whether each subfield emits or does not emit.

The data electrode drive circuit 42 converts the image data S41 for each subfield to data electrode drive signals S42 corresponding to each of the data electrodes D1 to Dm, and drives the data electrodes D1 to Dm.

The timing signal generating circuit 45 generates and supplies various timing signals S45 that control the operation of other circuit blocks to the other circuit blocks.

The scan electrode drive circuit 43 has an initialization waveform generating circuit (not shown in the figure), a sustain pulse generating circuit 50, and a scan pulse generating circuit (not shown in the figure).

The initialization waveform generating circuit generates the initialization waveform voltage that is applied to the scan electrodes SC1 to SCn in the initialization period.

The sustain pulse generating circuit 50 generates the sustain pulses applied to the scan electrodes SC1 to SCn in the sustain period.

The scan pulse generating circuit generates the scan pulse voltage applied to the scan electrodes SC1 to SCn in the address period.

The scan electrode drive circuit 43 generates a scan electrode drive signal S43 based on the timing signal output from the timing signal generating circuit 45, and drives each of the scan electrodes SC1 to SCn.

The sustain electrode drive circuit 44 includes a sustain pulse generating circuit 60, and a circuit for generating voltage Ve1 and voltage Ve2, and similarly generates sustain electrode drive signals S44 based on the timing signals S45A, and drives the sustain electrodes SU1 to SUn.

The configuration and operation of the sustain pulse generating circuit 50 and sustain pulse generating circuit 60 are described in detail next.

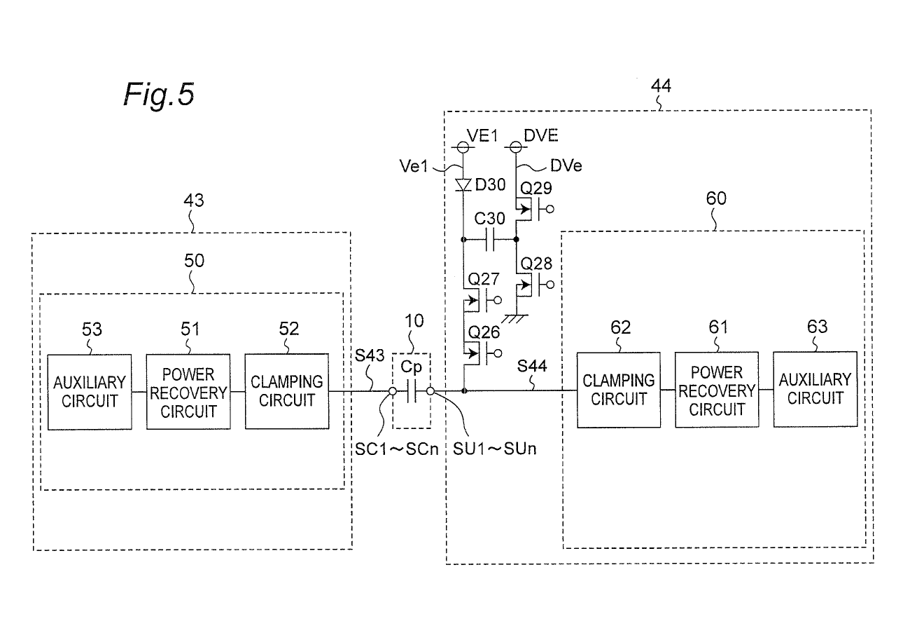

FIG. 5 is a block diagram of the sustain pulse generating circuit 50 and the sustain pulse generating circuit 60. In FIG. 5 the panel 10 is shown as an interelectrode capacitance Cp, and the scan pulse generating circuit and initialization waveform generating circuit are omitted.

The sustain pulse generating circuit 50 includes a power recovery circuit 51, a clamping circuit 52, and an auxiliary circuit 53.

The power recovery circuit 51 recovers the power accumulated in the interelectrode capacitance Cp, which is the capacitive load of the display electrode pair 24, into a recovery capacitor by means of LC resonance, and reuses the recovered power to drive the scan electrodes SC1 to SCn.

The clamping circuit 52 clamps the scan electrodes SC1 to SCn to voltage Vs and the ground potential.

The auxiliary circuit 53 provides auxiliary control of the current flowing to the scan electrodes SC1 to SCn from the recovery capacitor of the power recovery circuit 51 when driving the scan electrodes SC1 to SCn, and the current flowing from the interelectrode capacitance Cp to the recovery capacitor. The auxiliary circuit 53, power recovery circuit 51, and clamping circuit 52 are connected to the scan electrodes SC1 to SCn, which are one end of the interelectrode capacitance Cp of the panel 10, through the initialization waveform generating circuit and scan pulse generating circuit. During the sustain period the sustain pulse generating circuit 50 is electrically shorted to the scan electrodes SC1 to SCn, and the initialization waveform generating circuit and scan pulse generating circuit are electrically open. As a result, the initialization waveform generating circuit and scan pulse generating circuit are not shown in the figure.

Similarly to the sustain pulse generating circuit 50, the sustain pulse generating circuit 60 also has a power recovery circuit 61, a clamping circuit 62, and an auxiliary circuit 63. The auxiliary circuit 63, power recovery circuit 61, and clamping circuit 62 are connected to sustain electrodes SU1 to SUn, which are one end of the interelectrode capacitance Cp of the panel 10.

The sustain electrode drive circuit 44 also has a power source VE1, switching element Q26, switching element Q27, power source DVE, diode D30, capacitor C30, switching element Q28, and switching element Q29. The power source VE1 outputs voltage Ve1. Switching element Q26 and switching element Q27 switch applying voltage Ve1 to the sustain electrodes SU1 to SUn. Power source DVE produces voltage DVe. Diode D30 prevents current backflow to the power source VE1. Capacitor C30 functions as a charge pump adding voltage DVe to voltage Ve1. Switching element Q28 and switching element Q29 adds voltage DVe to voltage Ve1, and outputs voltage Ve2.

For example, at the timing when voltage Ve1 shown in FIG. 3 is applied, switching element Q26 and switching element Q27 are energized, and a positive voltage Ve1 is applied to sustain electrodes SU1 to SUn through diode D30, switching element Q26, and switching element Q27. At this time switching element Q28 is energized and charged until the voltage of capacitor C30 goes to voltage Ve1.

In addition, at the timing when voltage Ve2 in FIG. 3 is applied, switching element Q26 and switching element Q27 remain energized while switching element Q28 is cut off and switching element Q29 is energized. Voltage DVe is superposed on the voltage of capacitor C30, and voltage Ve1+DVe, that is, voltage Ve2, is applied to sustain electrodes SU1 to SUn. Backflow prevention diode D30 cuts off the current flow from the capacitor C30 to the power source VE1 at this time.

Note that the circuit for applying voltage Ve1 and voltage Ve2 is not limited to the circuit configuration shown in FIG. 5. For example, a configuration that uses a power source that produces voltage Ve1, a power source that produces voltage Ve2, and a plurality of switching elements that apply said voltages to the sustain electrodes SU1 to SUn can be used, and applies said voltages to the sustain electrodes SU1 to SUn at the required timing is also conceivable.

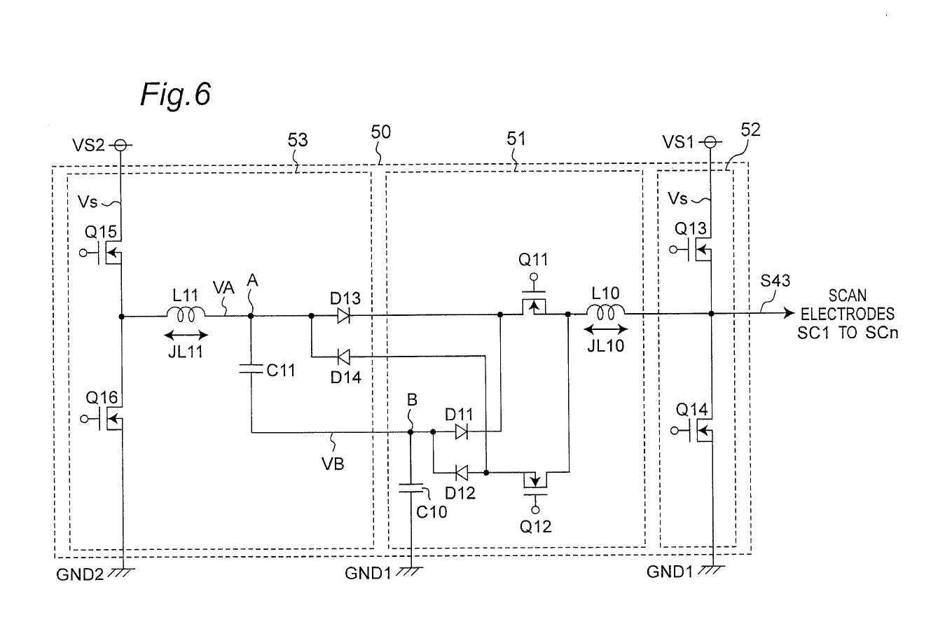

The configuration and operation of the auxiliary circuit 53, power recovery circuit 51, and clamping circuit 52 are described next. FIG. 6 is a circuit diagram of the sustain pulse generating circuit 50.

Potential is expressed as a positive, 0, or negative voltage between the ground terminal and any desired measurement point of the circuit.

Each of the power sources VS1, VS2 supplies potential Vs and a reference potential (the ground potential in the first embodiment of the invention) to the sustain pulse generating circuit 50 and sustain pulse generating circuit 60.

The sustain pulse generating circuit 50 supplies a sustain pulse identified by potential Vs and the reference potential through the scan electrode drive signal S43 to the scan electrodes SC1 to SCn in the sustain period.

The sustain pulse generating circuit 60 supplies the sustain pulse identified by potential Vs and the reference potential through the sustain electrode drive signal S44 to the sustain electrodes SU1 to SUn in the sustain period.

In the sustain period, the scan electrode drive signal S43 goes to the reference potential when the sustain electrode drive signal S44 is potential Vs, and goes to potential Vs when the sustain electrode drive signal S44 is the reference potential. In the sustain period, therefore, a positive voltage Vs and a negative voltage Vs are alternately applied to both ends of the n interelectrode capacitances Cp rendered between the scan electrodes SC1 to SCn and the sustain electrodes SU1 to SUn.

Note that because potential Vs and the reference potential represent a positive, 0, or negative voltage between the measurement point and the ground potential (0 V), they are also referred to as voltage Vs and a reference voltage (0 V in the first embodiment of the invention), respectively.

The configuration of the sustain pulse generating circuit 50 is outlined next below with reference to FIG. 6.

The sustain pulse generating circuit 50 drives the interelectrode capacitance Cp using power source VS1 and power source VS2. Power source VS1 is also referred to as a primary power supply, and power source VS2 is also referred to as an auxiliary power supply. The clamping circuit 52 supplies primary power from power source VS1 to interelectrode capacitance Cp, and holds (that is, clamps) the scan electrodes SC1 to SCn of interelectrode capacitance Cp to potential Vs and the reference potential.

The power recovery circuit 51 recovers primary power from interelectrode capacitance Cp while the sustain potential held in the clamping circuit 52 changes from potential Vs to the reference potential, and supplies the recovered primary power to the interelectrode capacitance Cp while the sustain potential changes from the reference potential to the potential Vs. In the stable period a specific time after the power source VS1 and power source VS2 are turned on, the power recovery circuit 51 recovers and supplies most of the primary power. By holding scan electrodes SC1 to SCn to the potential Vs and reference potential during this stable state, the clamping circuit 52 supplies the slightly deficient part of the primary power to the scan electrodes SC1 to SCn.

The auxiliary circuit 53 receives part of the primary power from the power recovery circuit 51 as auxiliary power, and receives auxiliary power from power source VS2. Based on the auxiliary power received from the auxiliary circuit 53, the power recovery circuit 51 rapidly recovers and supplies primary power.

The power recovery circuit 51 includes a capacitor C10 that can temporarily store the recovered primary power (that is, can store and discharge the primary power). The auxiliary circuit 53 includes a capacitor C11 that temporarily stores auxiliary power (that is, can store and discharge auxiliary power). One end of capacitor C11 is connected to one end of capacitor C10.

Auxiliary circuit 53 includes an inductor L11 connected to the other end of capacitor C11, and inductor L11 and capacitor C11 together produce LC resonance. Immediately before the sustain potential changes from potential Vs to the reference potential, the auxiliary circuit 53 receives part of the recovered primary power from capacitor C10 as auxiliary power, and sets the potential VA of the other end of capacitor C11 lower than the potential VB of the one end capacitor C10. Immediately before the sustain potential changes from the reference potential to the potential Vs, the auxiliary circuit 53 receives auxiliary power from power source VS2 and sets the potential VA of the other end of capacitor C11 higher than the potential of the one end of capacitor C10.

The configuration of the sustain pulse generating circuit 50 is described next from the point of view of the path through which the power supply and the current determined by the power supply flow.

The current flow based on the primary power is called the “primary current,” and the current flow based on the auxiliary power is called the “auxiliary current.”

The paths through which the primary power and primary current pass are the recovery path and supply path.

The paths through which the auxiliary power and auxiliary current pass include a recovery charge path, recovery discharge path, supply charge path, and supply discharge path. The recovery path recovers primary power from the interelectrode capacitance Cp to capacitor C10. The supply path supplies primary power from the capacitor C10 to the interelectrode capacitance Cp. The recovery charge path charges part of the primary power as auxiliary power from at least one of capacitor C10 and power source VS1 to capacitor C11. The recovery discharge path discharges the stored auxiliary power between interelectrode capacitance Cp and capacitor C11. The supply charge path charges auxiliary power from the power source VS2 to capacitor C11. The supply discharge path discharges the charged auxiliary power between capacitor C11 and the interelectrode capacitance Cp. At least part of the recovery path is shared with the recovery discharge path, and at least part of the supply path is shared with the supply discharge path.

Interelectrode capacitance Cp is also called a capacitive load.

The power recovery circuit 51 is also called a power feedback circuit, and the clamping circuit 52 is also called a sustain circuit. The potential Vs of power source VS1 is also called the primary potential, and the potential Vs of power source VS2 is also called an auxiliary potential. In the first embodiment of the invention the auxiliary potential is equal to the primary potential.

The capacitor C10 is also called a recovery capacitor, primary capacitance unit, or primary storage unit. Inductor L10 is also called a recovery inductor or primary inductance unit. Inductor L11 is also called an auxiliary inductance unit or auxiliary inductor, and capacitor C11 is also called an auxiliary storage unit or an auxiliary capacitance unit or an auxiliary capacitor. An auxiliary capacitance unit is an example of an auxiliary storage unit.

Note that the primary capacitance unit and auxiliary capacitance unit may be rendered using a plurality of capacitors, and the primary inductance unit and auxiliary inductance unit may be rendered using a plurality of inductors.

A first embodiment of the invention is described below in detail.

Power recovery circuit 51 includes capacitor C10, switching device Q11, switching device Q12, diode D11, diode D12, and inductor L10. Capacitor C10 is a recovery capacitor for power recovery. Switching device Q11 is a supply switch that conducts when supplying power from the capacitor C10 to scan electrodes SC1 to SCn. Switching device Q12 is a recovery switch that conducts when recovering power from the scan electrodes SC1 to SCn to the recovery capacitor C10.

Diode D11 prevents current backflow when supplying current forward from capacitor C10 to the scan electrodes SC1 to SCn. Diode D12 prevents current backflow when recovering power forward from the scan electrodes SC1 to SCn to the recovery capacitor C10.

Inductor L10 is a recovery inductor for LC resonance.

The power recovery circuit 51 also shapes the rising and falling edges of the sustain pulse by driving the interelectrode capacitance Cp and inductor L10 to produce LC resonance. The power recovery circuit 51 can thus drive the scan electrodes SC1 to SCn using LC resonance without having power supplied from power source VS1. The power recovery capacitor C10 has sufficiently greater capacitance than the interelectrode capacitance Cp, and so that it works as the power source of the power recovery circuit 51 is charged to approximately half of voltage Vs, that is, Vs/2. More specifically, one end of capacitor C10 (that is, node B) goes to potential VB (=Vs/2), and the other end is connected to ground terminal GND1 and goes to ground.

The clamping circuit 52 includes a switching device Q13 for clamping scan electrodes SC1 to SCn to potential Vs, and a switching device Q14 for clamping the scan electrodes SC1 to SCn to ground (0 (V)). The clamping circuit 52 connects and clamps the scan electrodes SC1 to SCn to power source VS1 and potential Vs through switching device Q13, and connects and clamps scan electrodes SC1 to SCn to ground terminal GND1 (also called the reference terminal) and potential 0 (V) through switching device Q14. Impedance is therefore low when applying voltage from the clamping circuit 52, and a strong discharge current can be stably supplied by means of a strong sustain discharge.

The auxiliary circuit 53 includes capacitor C11, inductor L11, switching device Q15, switching device Q16, diode D13, and diode D14. Capacitor C11 is an auxiliary capacitor connected in series to the power recovery capacitor C10. Inductor L11 is an auxiliary inductor used for LC resonance with capacitor C11. Switching device Q15 is a power supply side auxiliary switch that conducts when boosting the potential VA at node A of capacitor C11. Switching device Q16 is a reference potential side auxiliary switch that conducts when lowering the potential VA of capacitor C11. Diode D13 prevents the backflow of current flowing forward from capacitor C11 to inductor L10 when the sustain pulse rises. Diode D14 prevents the backflow of current flowing forward from mutual inductor L10 to capacitor C11 when the sustain pulse falls.

One terminal of capacitor C11 is connected to one terminal of capacitor C10 (that is, to node B), and another terminal of capacitor C11 (that is, node A) is connected to one terminal of inductor L11.

One terminal of switching device Q15 is connected to the other terminal of inductor L11, and the other terminal of switching device Q15 is connected to power source VS2 and goes to potential Vs.

One terminal of switching device Q16 is connected to the other terminal of inductor L11, that is, to the electrical connection between inductor L11 and switching device Q15, and the other terminal of switching device Q16 is connected to ground terminal GND2 (also called a reference terminal) and goes to the reference potential (in this embodiment of the invention the reference potential is the ground potential).

The anode of diode D13 is connected to the other terminal of capacitor C11, that is, to the electrical connection between inductor L11 and capacitor C11, and the cathode of diode D13 is connected to the electrical connection between switching device Q11 and diode D11.

The cathode of diode D14 is connected to the other terminal of capacitor C11, that is, to the node between inductor L11 and capacitor C11, and the anode of diode D14 is connected to the node between switching device Q12 and diode D12. The auxiliary circuit 53 in this first embodiment of the invention is thus rendered.

The sustain pulse generating circuit 50 opens and closes switching device Q11, switching device Q12, switching device Q13, switching device Q14, switching device Q15, and switching device Q16 based on a timing signal output from the timing signal generating circuit 45. As a result, the sustain pulse generating circuit 50 causes the power recovery circuit 51, clamping circuit 52, and auxiliary circuit 53 to operate and produce the sustain pulse waveform.

For example, at the rising edge of the sustain pulse, switching device Q11 is energized, LC resonance is produced between interelectrode capacitance Cp and inductor L10, and power is supplied to the scan electrodes SC1 to SCn from power recovery capacitor C10 through diode D11, switching device Q11, and inductor L10. When the potential of scan electrode drive signal S43 on scan electrodes SC1 to SCn is close to potential Vs, switching device Q13 is energized, the circuit driving scan electrodes SC1 to SCn is switched from power recovery circuit 51 to clamping circuit 52, and scan electrodes SC1 to SCn are clamped to potential Vs.

Conversely, at the falling edge of the sustain pulse, switching device Q12 is energized, interelectrode capacitance Cp and inductor L10 are made to resonate, and power is recovered from interelectrode capacitance Cp through inductor L10, switching device Q12, and diode D12 to the power recovery capacitor C10. When the potential of scan electrode drive signal S43 on scan electrodes SC1 to SCn approaches 0 (V), switching device Q14 is energized. As a result, the circuit driving scan electrodes SC1 to SCn switches from power recovery circuit 51 to clamping circuit 52, and scan electrodes SC1 to SCn are clamped to the reference potential, that is, 0 (V).

The sustain pulse generating circuit 50 thus produces sustain pulses. Note that these switching devices Q11, Q12, Q13, Q14, Q15, Q16 can be rendered using, for example, MOSFET (Metal Oxide Semiconductor Field Effect Transistor) or IGBT (Insulated Gate Bipolar Transistor) switching devices.

Capacitor C11 and inductor L11 render an auxiliary storage circuit. This auxiliary storage circuit temporarily stores part of the primary power recovered by the power recovery circuit 51 as auxiliary power, and temporarily stores auxiliary power from the power source VS2. Switching device Q15 and switching device Q16 render a switch unit. This switch unit connects the auxiliary storage circuit to the power source VS2 and sets it to potential Vs. Each of the switching devices Q11, Q12, Q13, Q14, Q15, Q16 is also simply called a switch. Switching device Q15 sets the auxiliary storage circuit to potential Vs when conductive, and switching device Q16 sets the auxiliary storage circuit to the reference potential when conductive.

In this first embodiment of the invention, immediately before the rise of the sustain pulse, the potential VA of capacitor C11 is set to a higher potential than the potential VB (=Vs/2) of capacitor C10, and immediately before the fall of the sustain pulse, the potential VA of capacitor C11 is set to a lower potential than potential VB of capacitor C10.

More specifically, immediately before power is supplied from capacitor C10 to scan electrodes SC1 to SCn and the sustain pulse rises, that is, immediately before switching device Q11 is energized, switching device Q15 is energized, causing capacitor C11 and inductor L11 to resonate. Power is then charged from power source VS2 through switching device Q15 and inductor L11 to capacitor C11, and the potential VA of capacitor C11 is set to a potential that is potential Vs greater than the potential VB (=Vs/2) of capacitor C10, that is, to 1.5 times potential Vs or 3Vs/2.

Switching device Q16 is also energized and capacitor C11 and inductor L11 made to resonate immediately before power is recovered from scan electrodes SC1 to SCn to capacitor C10 and the sustain pulse falls. Power from capacitor C11 is then discharged through inductor L11 and switching device Q16 to ground terminal GND2 at the reference potential, and the potential VA of capacitor C11 is set to potential Vs lower than the potential VB (=Vs/2) of capacitor C10, that is, to −Vs/2.

In this first embodiment of the invention as described above, the current JL10 flowing to the inductor L10 when the sustain pulse rises and falls is temporarily greater than the current that flows only as a result of the LC resonance of the inductor L10 and interelectrode capacitance Cp, the peak current when the sustain pulse is produced can be suppressed, reactive power can be reduced, and EMI can be reduced. This is described in further detail below.

The capacitance to which the LC resonance of inductor L11 is directed is the actual combined capacitance of capacitor C11 and capacitor C10, that is, Ca×Cb/(Ca+Cb) where Ca is the capacitance of capacitor C11 and Cb is the capacitance of capacitor C10. The capacitance of capacitor C11 is set to a value sufficiently lower than capacitor C10. For example, capacitor C10 is set to 8 μF, and capacitor C11 is set to 0.02 μF. As a result, the combined capacitance of capacitor C11 and capacitor C10 is described as actually being equal to the capacitance of capacitor C11.

The configuration of the sustain pulse generating circuit 60 is identical to the sustain pulse generating circuit 50. More specifically, the sustain pulse generating circuit 60 includes a power recovery circuit 61, clamping circuit 62, and auxiliary circuit 63.

The power recovery circuit 61 is configured identically to the power recovery circuit 51, the clamping circuit 62 is configured identically to the clamping circuit 52, and the auxiliary circuit 63 is configured identically to the auxiliary circuit 53. The sustain pulse generating circuit 60 is connected to the sustain electrodes SU1 to SUn, which are one side of the interelectrode capacitance Cp of the panel 10. The operation of the sustain pulse generating circuit 60 is the same as the operation of the sustain pulse generating circuit 50, and further description thereof is omitted.

The period of the LC resonance of the inductor L10 of the power recovery circuit 51 and the interelectrode capacitance Cp of the panel 10 (the “resonance period” below) can be obtained from the formula 2π√ (LCp) where L is the inductance of inductor L10. The resonance period of capacitor C11 and inductor L11 can also be similarly calculated.

In the first embodiment of the invention, inductor L10 is set so that the resonance period of the power recovery circuit 51 is approximately 2 μsec. The resonance period of the power recovery circuit 61 is set the same way.

In addition, the sustain pulse frequency is set to 100 kHz, the rise and fall periods of the sustain pulse are both 1 μsec, the sustain pulse is clamped to potential Vs for 3 μsec, and inductor L11 and capacitor C11 are set so that the resonance period of the auxiliary circuit 53 is approximately 6 μsec. The resonance period of the auxiliary circuit 63 is set the same way. Note, however, that these values are simply one example of a preferred embodiment of the invention, and as will be obvious to one with ordinary skill in the related art can be set desirably according to the characteristics of the panel and the specifications of the plasma display device.

The operation whereby the current JL10 flowing to the inductor L10 when the sustain pulse rises and falls is temporarily boosted above the current that flows due only to the LC resonance of the inductor L10 and interelectrode capacitance Cp is described next.

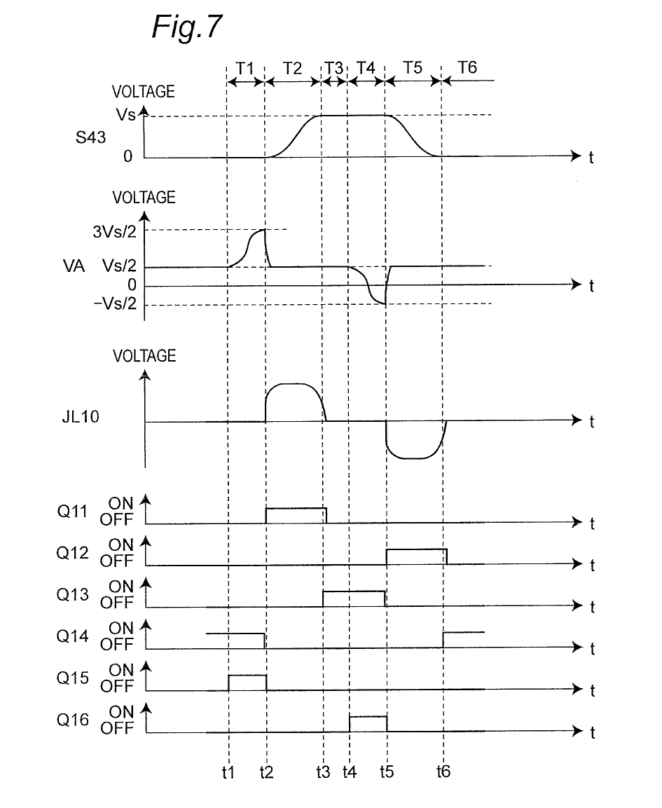

FIG. 7 is a timing chart describing the operation of the sustain pulse generating circuit. The operation producing a sustain pulse is divided into six periods T1 to T6, each of which is described below. Note that the operation of the sustain pulse generating circuit 50 is described below, and the operation of the sustain pulse generating circuit 60 is identical.

Shown in FIG. 7 are, from the top, the change in the voltage of scan electrode drive signal S43 applied to scan electrodes SC1 to SCn, the change in potential VA of capacitor C11 (at node A in FIG. 6) in the auxiliary circuit 53, the change in the current JL10 flowing to the inductor L10 (where the direction of flow to the scan electrodes SC1 to SCn is positive, and the direction of flow from the scan electrodes SC1 to SCn is negative), the control of switching device Q11, the control of switching device Q12, the control of switching device Q13, the control of switching device Q14, the control of switching device Q15, and the control of switching device Q16.

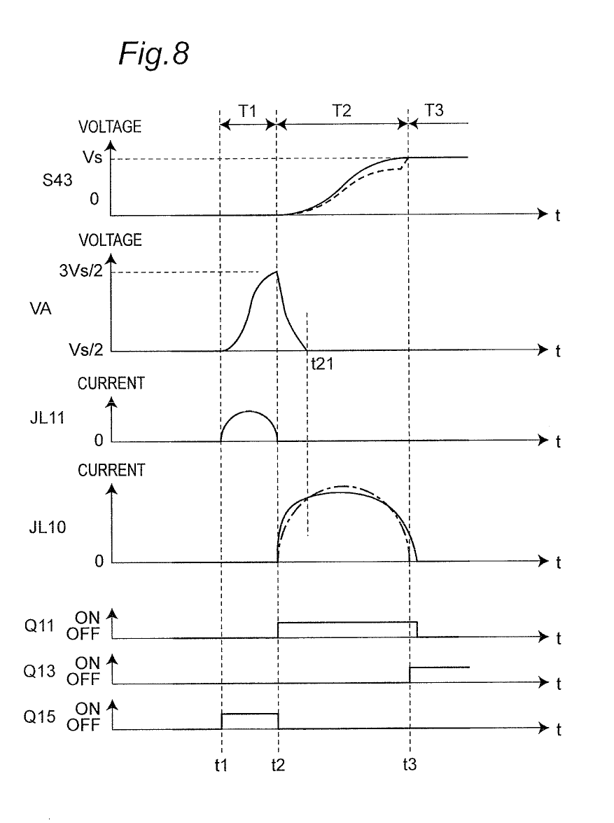

FIG. 8 shows periods T1 and T2 in the timing chart in FIG. 7 enlarged.

FIG. 8 shows, in order from the top, the change in the voltage of scan electrode drive signal S43 applied to scan electrodes SC1 to SCn, the change in potential VA of capacitor C11 (at node A in FIG. 6) in the auxiliary circuit 53, the change in the current JL11 flowing to inductor L11, the change in the current JL10 flowing to inductor L10, the control of switching device Q11, the control of switching device Q13, the control of switching device Q15, and the control of switching device Q16 [sic Q16 NOT SHOWN].

Note that below the operation energizing a switching device turns the switch on, opening (interrupting) the device turns the switch off, the signal that turns a switching device on is labelled ON, and the signal that turns a switching device off is labelled OFF.

In addition, a positive waveform representing a positive sustain pulse voltage Vs is shown in FIG. 7 and described below, but the invention is not so limited. For example, in an embodiment related to a negative waveform representing a negative sustain pulse voltage Vs, the same effect can be achieved with a negative waveform by reading the “rising edge” of a positive waveform in the following description as the “falling edge” of a negative waveform.

### (Period T1)

At time t1, switching device Q15 turns on. As a result, current JL11 flows to capacitor C11 from power source VS2 through switching device Q15 and inductor L11, and the potential VA (the potential at node A in the figures) of capacitor C11 begins to rise.

Current JL11 is also called an auxiliary current, and the path through which this flow auxiliary current is also called the supply charge path. The potential VB of capacitor C10 is Vs/2, and capacitor C11 and inductor L11 render a resonance circuit. As a result, at time t2 when ½ of the resonance period has passed, the potential VA of capacitor C11 rises to Vs/2+Vs, that is, to nearly 3Vs/2.

During this time switching device Q14 is held on, and scan electrodes SC1 to SCn are clamped to 0 (V).

### (Period T2)

Next at time t2, switching device Q14 and switching device Q15 turn off and switching device Q11 turns on.

Because inductor L10 and interelectrode capacitance Cp render a resonance circuit, auxiliary current flows as a result of this switching operation from capacitor C11, which was charged so that the potential at node A goes to 3Vs/2, through diode D13, switching device Q11, and inductor L10 to the scan electrodes SC1 to SCn. This path through which the auxiliary current flows is also called the supply discharge path. Current also flows from power recovery capacitor C10 through diode D11, switching device Q11, and inductor L10 to scan electrodes SC1 to SCn. This current is also called the primary current, and the path through which the primary current flows is also called the supply path. The current JL10 shown in FIG. 7 and FIG. 8 is the sum of the primary current and auxiliary current flowing through inductor L10. As a result, the potential of scan electrode drive signal S43 on scan electrodes SC1 to SCn begins to rise.

For example, if the resonance period of inductor L10 and interelectrode capacitance Cp is set to approximately 2 μsec, the potential of the scan electrode drive signal S43 on scan electrodes SC1 to SCn rises to near potential Vs approximately 1 μsec after time t2.

At this time in the first embodiment of the invention, auxiliary current flows to scan electrodes SC1 to SCn from capacitor C11, which was charged so that node A in the auxiliary circuit 53 goes to potential VA (=3Vs/2). As a result, as shown by the solid line in the waveform in FIG. 8 showing the change in current JL10 flowing through inductor L10, the rising edge of the current JL10 flowing to scan electrodes SC1 to SCn rises more sharply in the forward direction than the current rise when auxiliary circuit 53 is not used as denoted by the dot-dash line.

Yet further, in the first embodiment of the invention the capacitance of capacitor C11 is sufficiently lower than capacitor C10 (in this embodiment the capacitance of capacitor C10 is 8 μF, and the capacitance of capacitor C11 is 0.02 μF). Therefore, as shown by the waveform of the change in the potential VA of capacitor C11 (node A in FIG. 6) in FIG. 7 and FIG. 8, the potential VA of capacitor C11 drops sharply as a result of supplying power from capacitor C11 to scan electrodes SC1 to SCn. The potential difference between the positive and negative sides of capacitor C11 at time t21 a relatively short time after time t2 is 0, and the potential VA of capacitor C11 goes to the same potential (potential Vs/2) as the potential VB of capacitor C10. As a result, the power supply from capacitor C11 to scan electrodes SC1 to SCn stops while power is supplied from capacitor C10 to scan electrodes SC1 to SCn. Thereafter, only the power output from capacitor C10 is supplied to scan electrodes SC1 to SCn.

The power stored in capacitor C11 thus causes the current JL10 flowing through inductor L10 to scan electrodes SC1 to SCn to increase temporarily and rise sharply when the sustain pulse rises. In addition, because the power supply from capacitor C11 to scan electrodes SC1 to SCn stops while power is supplied from capacitor C10 to scan electrodes SC1 to SCn, the peak current JL10 flowing through inductor L10 depends on the resonance period of inductor L10 and interelectrode capacitance Cp.

The reason why the current JL10 flowing to j10 is temporarily boosted when the sustain pulse rises (falls) in this first embodiment of the invention is described next.

As panel definition has increased, the number of electrodes that must be addressed in one subfield period has also increased. As a result, the time required for one address period also tends to increase, but because the amount of time that can be allocated to one subfield is limited, it is necessary to shorten the sustain period by, for example, shortening the period of the sustain pulse.

On the other hand, in order to produce a stable sustain discharge, it is necessary to consider such interference factors as the delay in producing a discharge, generally called the discharge delay, and variation in the discharge delay in different discharge cells.

The discharge delay represents the time from when the voltage applied to a discharge cell exceeds the discharge start voltage until the actual discharge is produced. Due to these factors, a sufficient clamping period for clamping the sustain pulse to the potential Vs of power source VS1 and the ground potential must be assured. In order to shorten the sustain pulse period while also assuring a sufficient clamping period, it is necessary to make the sustain pulse rise and fall rapidly and shorten the sustain pulse rise and fall times.

Furthermore, if the discharge is produced with a sharp voltage change in the sustain operation, a strong discharge can be produced and a sufficient wall charge can be stored in the discharge cell. The effect of producing a stable discharge can also be improved because variation in the discharge start voltage can be absorbed and deviation in the sustain discharge between discharge cells can be suppressed by producing a discharge when there is a sharp voltage change.

It is therefore preferable to increase the current of the scan electrode drive signal S43 supplied from the sustain pulse generating circuit 50 to the scan electrodes SC1 to SCn as quickly as possible so that the sustain pulse rises as quickly as possible.

In order to achieve a sharp rising or falling edge to the sustain pulse, the inductance of inductor L10, which is a recovery inductor, can be reduced to shorten the resonance period of the inductor L10 and interelectrode capacitance Cp, for example. However, if the resonance period of the recovery inductor L10 and interelectrode capacitance Cp is shortened, the maximum value of the current (the peak current) moving between the recovery capacitor C10 and interelectrode capacitance Cp increases and EMI increases.

In addition, if the peak current increases, the amount of power that is consumed needlessly without contributing to emission, that is, reactive power, also increases. Because the drive load is also higher in a high definition panel, reactive power may also increase.

Furthermore, because the output impedance of the power recovery circuit 51 is high relative to the output impedance of the clamping circuit 52, the increase in peak current produces waveform distortion called “ringing” due, for example, to the effect of the drive load. Such waveform distortion destabilizes discharge and increases reactive power.

Furthermore, because the voltage drop increases correspondingly to the rise in the peak current, the voltage applied by the scan electrode drive signal S43 to the scan electrodes SC1 to SCn does not rise to voltage Vs when driven by the power recovery circuit 51 as indicated by the dotted line in the waveform showing the change in the voltage of the scan electrode drive signal S43 applied to scan electrodes SC1 to SCn in FIG. 8. As a result, the power supplied from power source VS1 to scan electrodes SC1 to SCn when switching to the immediately following clamping circuit 52 increases, and power consumption rises.

However, if the resonance period of the power recovery circuit 51 that, for example, increases the inductance of the inductor L10 becomes longer, the slope of the rise in the current JL10 supplied from the power recovery circuit 51 to the scan electrodes SC1 to SCn becomes more gradual. As a result, EMI can be reduced and reactive power can be reduced because the maximum value of the current (the peak current) moving between the capacitor C10 and the interelectrode capacitance Cp is reduced. Yet further, because the voltage drop is suppressed, the voltage of the scan electrode drive signal S43 applied to the scan electrodes SC1 to SCn when driven by the power recovery circuit 51 can be boosted to a potential closer to voltage Vs. As a result, the power supplied from power source VS1 to the scan electrodes SC1 to SCn when switching to the following clamping circuit 52 can be reduced, and power consumption can be reduced.

However, if the resonance period of the power recovery circuit 51 is increased and the edge characteristic describing the slope of the rising and falling edges of the sustain pulse becomes more gradual, the sustain period increases accordingly, and this is a problem.

In order to reduce EMI and reactive power while stably driving a high definition panel, it is therefore necessary due to the foregoing to balance the mutually contradictory operations of achieving the sharpest possible edge characteristic when producing the sustain pulse while also decreasing the maximum value of the current, that is, the peak current, flowing between the sustain pulse generating circuit 50 and interelectrode capacitance Cp.

The auxiliary circuit 53 is used in this first embodiment of the invention to enable this operation, and is a circuit enabling rendering a sharp edge characteristic when producing sustain pulses while also reducing the peak current flow between the sustain pulse generating circuit and interelectrode capacitance Cp.

More specifically, immediately before the rise of the sustain pulse, the capacitor C11 is charged from power source VS2 by the LC resonance of capacitor C11 and inductor L11, and the potential VA of capacitor C11 is boosted to a potential (in this embodiment of the invention, 3Vs/2) higher than the potential VB of capacitor C10.

Immediately before the sustain pulse falls, the LC resonance of capacitor C11 and inductor L11 discharges the power in capacitor C11 to ground terminal GND2 at the reference potential, and drives the potential VA of capacitor C11 to a lower potential (in this embodiment of the invention, −Vs/2) than the potential VB of capacitor C10. As a result, immediately after the power recovery circuit 51 starts operating, power moves between capacitor C11 and interelectrode capacitance Cp, and the current JL10 flowing to inductor L10 can temporarily be boosted above the current flow resulting only from the LC resonance of inductor L10 and interelectrode capacitance Cp. More specifically, at the rising edge and the falling edge of the sustain pulse, the current level of the scan electrode drive signal S43 that moves between the sustain pulse generating circuit 50 and the interelectrode capacitance Cp can be temporarily increased, and the sustain pulse can be rendered with a sharp edge characteristic without shortening the resonance period of the inductor L10 and interelectrode capacitance Cp.

In addition, because the capacitance of capacitor C11 is set sufficiently lower than the capacitance of capacitor C10, the increase in the inductor L10 current JL10 that occurs immediately after the power recovery circuit 51 starts operating is transient. As a result, the peak current of the scan electrode drive signal S43 flowing between the sustain pulse generating circuit and the interelectrode capacitance Cp is determined by the resonance period of inductor L10 and interelectrode capacitance Cp. As a result, by setting the inductance of inductor L10 so that the resonance period of inductor L10 and interelectrode capacitance Cp becomes longer, the peak current flowing between the sustain pulse generating circuit and the interelectrode capacitance Cp can be suppressed.

The dot-dash line of current JL10 in FIG. 8 shows the power supply to the scan electrodes SC1 to SCn in a power recovery circuit in which the inductance of the inductor L10 is lower than in the first embodiment, the resonance period is shortened, and auxiliary circuit 53 is not used. As shown by the difference between the waveform denoted by this dot-dash line and the waveform of the first embodiment denoted by the solid line, the configuration of the first embodiment can render a sharper rising edge to the current JL10 flowing from the power recovery circuit 51 to the scan electrodes SC1 to SCn at the rise of the sustain pulse in period T2, and can suppress peak current.

By reducing the peak current, reactive power can be reduced and EMI can be reduced while a stable sustain discharge can be produced by reducing ringing as a result of the lower peak current. In addition, by reducing reactive power, the voltage of the scan electrode drive signal S43 applied to scan electrodes SC1 to SCn can be boosted to a potential closer to voltage Vs (actually to potential Vs in this embodiment of the invention). As a result, while improving the power efficiency of the power recovery circuit 51, the power supplied from power source VS1 to scan electrodes SC1 to SCn when switching immediately to the following clamping circuit 52 can be suppressed, and power consumption can be further reduced.

### (Period T3)

At time t3 switching device Q13 turns on. As a result, the scan electrodes SC1 to SCn are connected through device Q13 directly to power source VS1.

In the first embodiment of the invention, because the potential of scan electrodes SC1 to SCn is actually driven to potential Vs by power recovery circuit 51, no real change is produced in the potential of scan electrodes SC1 to SCn even if scan electrodes SC1 to SCn are clamped to potential Vs. As a result, the power supplied from clamping circuit 52 to scan electrodes SC1 to SCn can be reduced. In addition, switching device Q13 is also held on in the following period T4, and as a result in period T3 and period T4 the potential of scan electrode drive signal S43 on scan electrodes SC1 to SCn is held to potential Vs.

### (Period T4)

At time t4, switching device Q16 turns on. As a result, auxiliary current JL11 flows from capacitor C10 through capacitor C11, inductor L11 and switching device Q16 to ground terminal GND2 at the reference potential, and the potential VA (the potential at node A in the figures) of capacitor C11 begins to fall.

This path through which the auxiliary current flows is also called the recovery charge path. The potential VB of capacitor C10 is Vs/2, and capacitor C11 and inductor L11 render a resonance circuit. As a result, at time t5 after a time equal to ½ the resonance period passes, the potential VA of capacitor C11 goes to Vs/2−Vs, that is, drops to approximately −Vs/2.

### (Period T5)

Next, switching device Q13 and switching device Q16 turn off and switching device Q12 turns on at time t5.

Because inductor L10 and interelectrode capacitance Cp render a resonance circuit, this switching operation causes auxiliary current to flow from scan electrodes SC1 to SCn through inductor L10, switching device Q12, and diode D14 to the capacitor C11, which is charged so that node A goes to potential −Vs/2. This path through which the auxiliary current flows is also called the recovery discharge path.

Primary current also flows from scan electrodes SC1 to SCn through inductor L10, switching device Q12, and diode D12 to the power recovery capacitor C10. This path through which the primary current flows is also called the recovery path. Current JL10 is the sum of the primary current and auxiliary current flowing through inductor L10. As a result, the potential of scan electrode drive signal S43 on begins to drop.

For example, when the resonance period of inductor L10 and interelectrode capacitance Cp is set to approximately 2 μsec, the potential of the scan electrode drive signal S43 on scan electrodes SC1 to SCn drops to near the ground potential approximately 1 μsec after time t5.

At this time in the first embodiment of the invention, auxiliary current flows from scan electrodes SC1 to SCn to capacitor C11, which is charged so that node A in the auxiliary circuit 53 goes to potential −Vs/2. As a result, for the same reason described in period T2 above, the drop in the potential of scan electrode drive signal S43 flowing from scan electrodes SC1 to SCn to sustain pulse generating circuit 50 (described here as a drop because the direction of flow from scan electrodes SC1 to SCn to the sustain pulse generating circuit 50 at this time is negative) is sharper (that is, rises sharply in the negative direction) than when the auxiliary circuit 53 is not used.

As a result, compared with when recovering power from the scan electrodes SC1 to SCn to the power recovery circuit in a configuration that does not use an auxiliary circuit 53, the drop in the current JL10 flowing from the scan electrodes SC1 to SCn to the power recovery circuit 51 at the falling edge of the sustain pulse in period T5 is sharp, and the peak current flowing to the inductor L10 can be suppressed.

It is therefore possible to reduce reactive power and reduce EMI by reducing the peak current, and a stable sustain discharge can be produced by reducing ringing as a result of reducing the peak current. In addition, by reducing reactive power, the voltage of the scan electrode drive signal S43 applied to scan electrodes SC1 to SCn can be lowered to a potential closer to the ground potential (actually to the ground potential in this embodiment of the invention). As a result, the power recovery efficiency of the power recovery circuit 51 can be improved, the amount of power that is discharged from the scan electrodes SC1 to SCn to the ground terminal GND1 when switching immediately thereafter to the clamping circuit 52 can be suppressed, and power consumption can be further reduced.

Yet further, reactive power can be reduced by suppressing the peak current, and as a result the potential of the scan electrode drive signal S43 on the scan electrodes SC1 to SCn can be lowered to substantially the ground potential. The power consumed when switching immediately thereafter to the clamping circuit 52 can therefore be suppressed, and reactive power can be further reduced.

### (Period T6)

At time t6 switching device Q14 turns on. As a result, scan electrodes SC1 to SCn go directly to ground through switching device Q14.

Because the potential of the scan electrode drive signal S43 on the scan electrodes SC1 to SCn actually goes to 0 (V), the ground potential, as a result of power recovery circuit 51 drive, there is no real change in the potential of the scan electrodes SC1 to SCn even if the scan electrodes SC1 to SCn are clamped to ground. As a result, power consumption by the clamping circuit 52 can be reduced.

Switching device Q11 turns off from time t3 to time t4, and switching device Q12 turns off from time t6 to the next time t1. In addition, to lower the output impedance of the sustain pulse generating circuit 50, switching device Q13 preferably turns off immediately before time t5, and switching device Q14 preferably turns off immediately before time t2.

The operation of the sustain pulse generating circuit 50 is described above. The operation of the sustain pulse generating circuit 60 is identical, and further description thereof is thus omitted.

In the sustain pulse, the foregoing operation in period T1 to period T6 repeats for the required number of pulses. As a result, the sustain pulse voltage that changes between 0 (V), which is the reference potential, and potential Vs can be alternately applied to each of the display electrode pairs 24 and a sustain discharge can be produced in the discharge cells.

With the first embodiment of the invention as described above, the current JL10 flow to the recovery inductor (inductor L10 in power recovery circuit 51) at the rising and falling edges of the sustain pulse can be rapidly increased by using an auxiliary circuit 53. As a result, even if the panel resolution is increased and the sustain pulse period is shortened, a sufficient sustain pulse clamping period can be assured, and by increasing the resonance period of the recovery inductor and interelectrode capacitance Cp, the peak current flow between the recovery inductor and interelectrode capacitance Cp can be reduced. As a result, a stable sustain discharge can be produced by assuring a sufficient clamping period even in a high resolution panel, and power consumption and EMI can be reduced by reducing the peak current.

In the first embodiment of the invention the resonance period of inductor L11 and capacitor C11 is described as being approximately 6 μsec. This is because the sustain pulse frequency is 100 kHz, the rise and fall times of the sustain pulse (period T2 and period T5 in FIG. 7) are each 1 μsec, and the time the sustain pulse is clamped to potential Vs is 3 μsec. The first embodiment of the invention is thus preferably configured so that the capacitor C11 can be charged during the clamping period when producing a sustain pulse. To achieve this, the half resonance period of the inductor L11 and capacitor C11 is preferably set to less than the time the display electrode pairs are clamped to the potential Vs of power source VS1 (the period from time t3 to time t5 in FIG. 7), and to less than the time the display electrode pairs are clamped to the ground potential (the time from time t6 to the next time t2 in FIG. 7).

The first embodiment of the invention describes a configuration in which the capacitance of capacitor C10 is 8 μF and the capacitance of capacitor C11 is 0.02 μF, but it should be noted that in order to produce a sustain pulse with a sufficiently sharp rising edge while also suppressing peak current, the capacitance of capacitor C11 is preferably 1/10 the capacitance of capacitor C10 or less.

The first embodiment of the invention describes a configuration in which the auxiliary circuit 53 has one resonance circuit, but the same operation can be achieved with other configurations. Other configurations of the auxiliary circuit are described below.

### Embodiment 2

This second embodiment of the invention describes the configuration of an auxiliary circuit that uses two resonance circuits. Primarily the differences between this and the first embodiment are described below. Other aspects of the configuration, operation, and effect of this embodiment are substantially the same as in the first embodiment, and further description thereof is thus omitted.

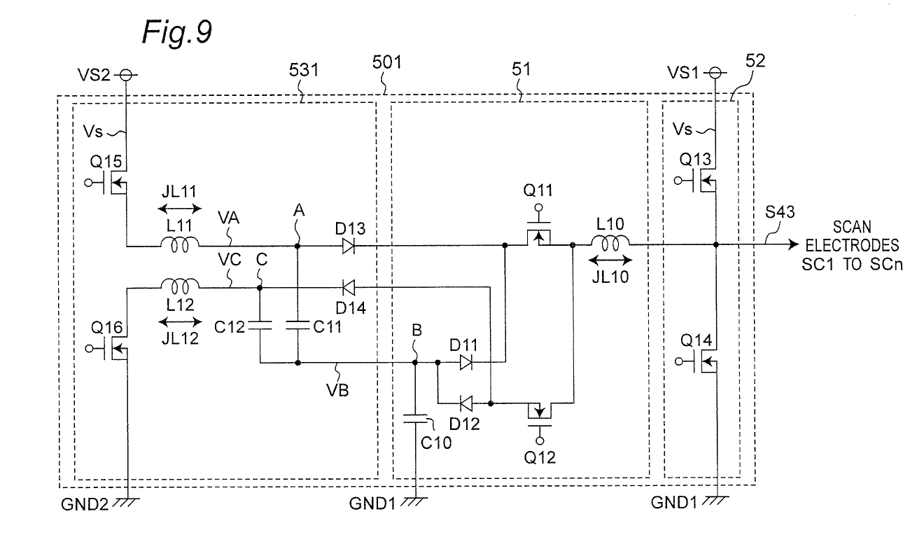

FIG. 9 is a circuit diagram of the sustain pulse generating circuit 501. This sustain pulse generating circuit 501 includes a power recovery circuit 51, clamping circuit 52, and auxiliary circuit 531. The power recovery circuit 51 and clamping circuit 52 have the same configuration and operate identically to the power recovery circuit 51 and clamping circuit 52 described in the first embodiment described above, and further description thereof is omitted here.

The auxiliary circuit 531 includes a capacitor C11, capacitor C12, inductor L11, inductor L12, switching device Q15, switching device Q16, diode D13, and diode D14. Capacitor C11 is a power supply side auxiliary capacitor connected in series with power recovery capacitor C10. Capacitor C12 is a reference potential side auxiliary capacitor connected in series with power recovery capacitor C10.

Inductor L11 is an auxiliary inductor that is used when charging power from the power source VS2 to the capacitor C11 using LC resonance with capacitor C11. Inductor L12 is an auxiliary inductor that is used when discharging power from capacitor C12 to the ground terminal GND2 at the reference potential by means of LC resonance with capacitor C12.

Switching device Q15 is a power supply side auxiliary switch that conducts when boosting the potential VA of capacitor C11.

Switching device Q16 is a reference potential side auxiliary switch that conducts when lowering the potential VC at node C of capacitor C12.

Diode D13 is a diode that prevents the backflow of current flowing forward from capacitor C11 to inductor L10 during the sustain pulse rise.

Diode D14 is a diode that prevents the backflow of current flowing forward from inductor L10 to capacitor C12 at the falling edge of the sustain pulse.

One terminal of capacitor C11 is connected to one terminal of capacitor C10 (that is, node B), and the other terminal of capacitor C11 (that is, node A) is connected to one terminal of inductor L11.

One terminal of capacitor C12 is connected to the electrical node between capacitor C10 and capacitor C11, and the other terminal of capacitor C12 (that is, node C) is connected to one terminal of inductor L12.

In addition, one terminal of switching device Q15 is connected to the other terminal of inductor L11, and the other terminal of switching device Q15 is connected to power source VS2 and goes to potential Vs.

The one terminal of switching device Q16 is connected to the other terminal of inductor L12, and the other terminal of switching device Q16 is connected to ground terminal GND2 and goes to the ground potential, which is the reference potential.

The anode of diode D13 is connected to the connection node between capacitor C11 and inductor L11, and the cathode of diode D13 is connected to the connection node between switching device Q11 and diode D11.

The cathode of diode D14 is connected to the node between capacitor C12 and inductor L12, and the anode of diode D14 is connected to the node between switching device Q12 and diode D12. The auxiliary circuit 531 is thus rendered.

Note that capacitor C11, inductor L11, capacitor C12, and inductor L12 render an auxiliary storage circuit.

Switching device Q15 sets the auxiliary storage circuit to potential Vs when energized, and switching device Q16 sets the auxiliary storage circuit to the reference potential when energized.

The auxiliary storage circuit includes two secondary auxiliary storage circuits. Capacitor C11 and inductor L11 render one second auxiliary storage circuit, and capacitor C12 and inductor L12 render another secondary auxiliary storage circuit.

When energized, the switching device Q15 sets the secondary auxiliary storage circuit including capacitor C11 and inductor L11 to potential Vs. When energized, switching device Q16 sets the other secondary auxiliary storage circuit including capacitor C12 and inductor L12 to the reference potential. Capacitor C11 and capacitor C12 render auxiliary capacitance units (that is, are examples of an auxiliary storage unit). Capacitors C11, C12 are also called secondary auxiliary capacitance units. Inductor L11 and inductor L12 render an auxiliary inductance unit. Inductors L11, L12 are also called secondary auxiliary inductance units.

Immediately before power is supplied from capacitor C10 to scan electrodes SC1 to SCn and the sustain pulse rises, that is, immediately before switching device Q11 is energized, switching device Q15 is energized to produce LC resonance in capacitor C11 and inductor L11, power is charged from VS2 through switching device Q15 and inductor L11 to capacitor C11, and the potential VA of capacitor C11 is set to potential 3Vs/2, which is potential Vs greater than the potential VB (=Vs/2) of capacitor C10.

Immediately before power is recovered from scan electrodes SC1 to SCn to capacitor C10 and the sustain pulse falls, that is, immediately before switching device Q12 is energized, switching device Q16 is energized to produce LC resonance between capacitor C11 and inductor L11, the power stored in capacitor C11 is discharged through inductor L11 and switching device Q16 to ground terminal GND2 at the reference potential, and the potential VA of capacitor C11 is set to a potential −Vs/2 that is potential Vs lower than the potential VB of capacitor C10 (=Vs/2).

As described in the first embodiment of the invention above, the current JL10 flow to the recovery inductor (inductor L10 in power recovery circuit 51) at the rising and falling edges of the sustain pulse can be rapidly increased by using an auxiliary circuit 531. As a result, even if the panel resolution is increased and the sustain pulse period is shortened, a sufficient sustain pulse clamping period can be assured, and by increasing the resonance period of the recovery inductor and interelectrode capacitance Cp, the peak current flow between the recovery inductor and interelectrode capacitance Cp can be reduced. As a result, a stable sustain discharge can be produced by assuring a sufficient clamping period even in a high resolution panel, and power consumption and EMI can be reduced by reducing the peak current.

In addition, the auxiliary capacitance in this second embodiment is divided into a power supply side auxiliary capacitance (capacitor C11 in FIG. 9) that is used when setting a higher potential than the recovery capacitor, and a reference potential side auxiliary capacitance (capacitor C12 in FIG. 9) that is used when setting a lower potential than the recovery capacitor. As a result, by setting the power supply side auxiliary capacitor and the reference potential side auxiliary capacitor to different capacitances, current control at the rising edge of the sustain pulse and current control at the falling edge can be set differently.

The first embodiment of the invention describes a configuration in which the half resonance period of inductor L11 and capacitor C11 is shorter than the clamping period. In this second embodiment of the invention, however, the auxiliary capacitance unit is separated into capacitor C11 and capacitor C12, and the auxiliary inductance unit is separated into inductor L11 for capacitor C11 and inductor L12 for capacitor C12. As a result, the resonance period of the auxiliary capacitor and auxiliary inductor can be set longer, and the peak current that changes dependently upon the resonance period can be further suppressed. Here the peak current is the peak current JL11 flowing from power source VS2 through inductor L11 to capacitor C11, and the peak value of the current JL12 flow from capacitor C12 through inductor L12 to ground terminal GND2.

More specifically, the sustain pulse frequency is 100 kHz (that is, the sustain pulse period is 10 μsec), and the sustain pulse rise and fall periods are each 1 μsec. With this configuration, the period for charging capacitor C11, for example, may be a maximum 9 μsec, that is, the sustain pulse period not including the sustain pulse rise time (period T2 in FIG. 7). Therefore, the resonance period of capacitor C11 and inductor L11 can be set to a maximum 18 μsec. Similarly, the period for charging capacitor C12 can be set at most to the sustain pulse period minus the sustain pulse fall time (period T5 in FIG. 7), and the maximum resonance period of capacitor C12 and inductor L12 can be set accordingly.

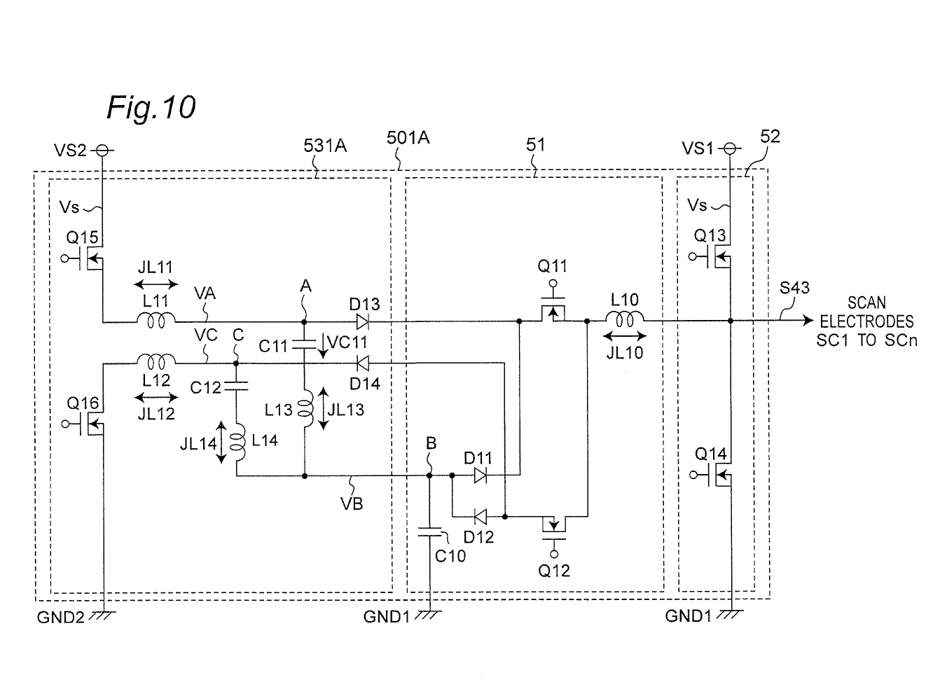

FIG. 10 is a circuit diagram of the sustain pulse generating circuit 501A in the second embodiment of the invention. The sustain pulse generating circuit 501A shown in FIG. 10 differs from the sustain pulse generating circuit 501 in FIG. 9 in that inductor L13 and inductor L14 are connected in series to capacitor C11 and capacitor C12, and auxiliary circuit 531 is therefore changed to auxiliary circuit 531A. Only these differences are therefore described below.

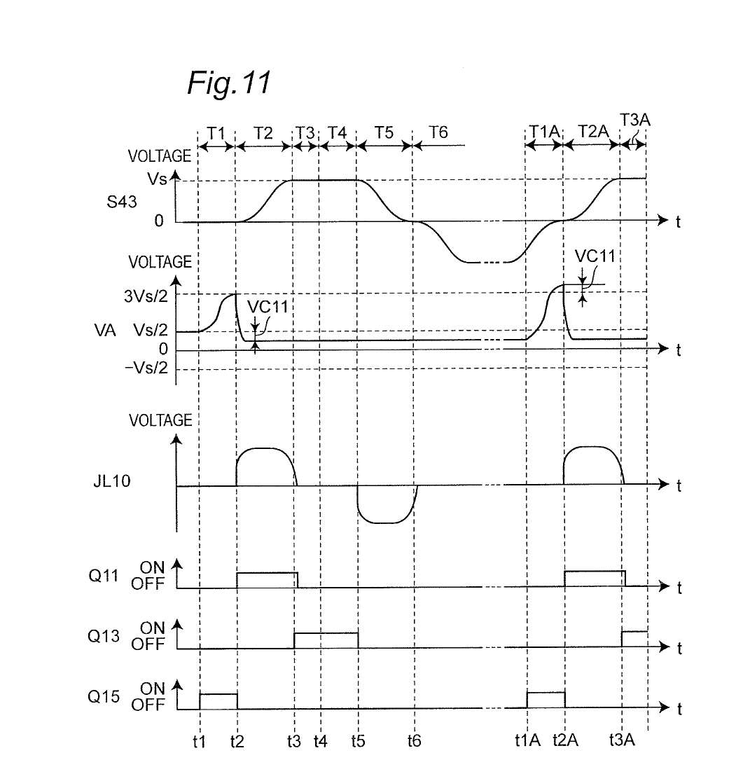

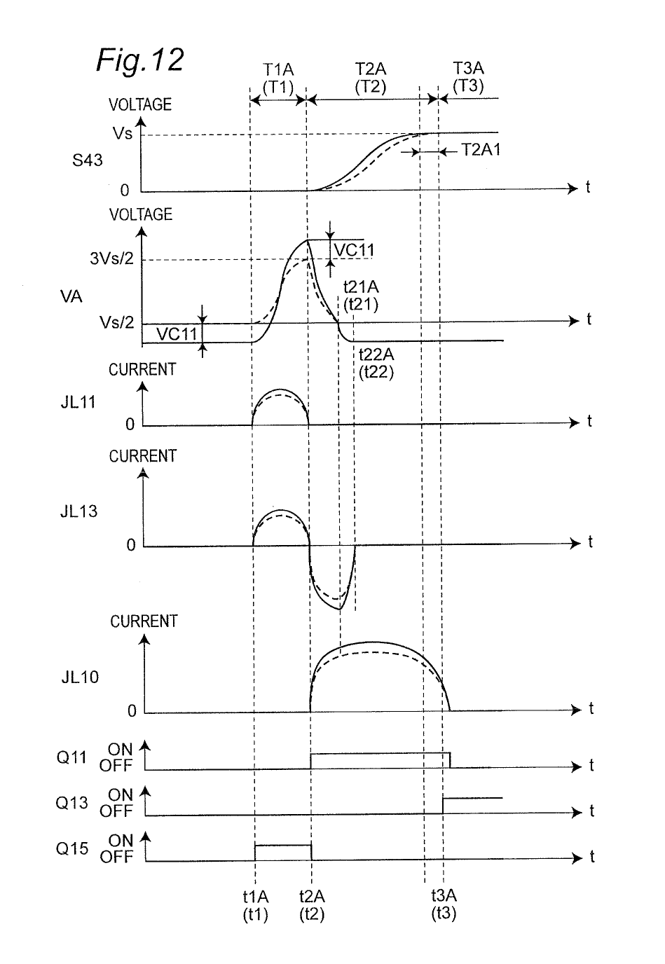

FIG. 11 is a timing chart describing the operation of the sustain pulse generating circuit 501A. FIG. 12 is an enlarged view of period T1 and period T2 in the timing chart in FIG. 11.

In FIG. 12, the broken lines in the potential S43 of scan electrodes SC1 to SCn, the potential VA of capacitor C11, the current JL11 of inductor L11, the inductor L13 current JL13, and the inductor L10 current JL10 show the waveforms produced the first time switching device Q15 operates, and the solid lines denote the waveforms resulting from the second and subsequent operations. Periods T1, T2, T3 in parentheses, and times t1, t2, t21, t22, t3 in parentheses are related to the waveforms resulting from the first operation. Periods T1A, T2A, T3A, and times t1A, t2A, t21A, t22A, t3A are related to the waveforms resulting from the second and later operations.

As shown in FIG. 10, the auxiliary circuit 531A includes capacitor C11, capacitor C12, inductor L13, inductor L14, inductor L11, inductor L12, switching device Q15, switching device Q16, diode D13, and diode D14.

One terminal of inductor L13 is connected to one terminal of capacitor C11, and the other terminal of inductor L13 is connected to one terminal of capacitor C10 (that is, node B). In addition, one terminal of inductor L14 is connected to one terminal of capacitor C12, and the other terminal of inductor L14 is connected to one terminal of capacitor C10 (that is, node B).

As described with reference to FIG. 8, the first time switching device Q15 operates, inductor L11 and capacitor C11 resonate, and the potential VA of capacitor C11 goes to 3Vs/2. When switching device Q11 then turns on, auxiliary current flows from capacitor C11 through diode D13, switching device Q11, and inductor L10 to scan electrodes SC1 to SCn.

When the charge in capacitor C11 dissipates and the voltage of capacitor C11 goes to 0V (time t21 in FIG. 12), capacitor C11 is charged in reverse to reverse voltage VC11 by the current JL13 flow to inductor L13. The current JL13 of inductor L13 goes to 0 A, and reverse charging of capacitor C11 ends (at time t22 in FIG. 12). Thereafter, primary current flows from capacitor C10 through diode D11, switching device Q11, and inductor L10 to scan electrodes SC1 to SCn. Discharge of reverse voltage VC11 from capacitor C11 is prevented by diode D13, and the capacitor C11 remains charged. As shown in FIG. 11, the potential VA of capacitor C11 at this time is Vs/2−VC11 to time t1A.

The second time switching device Q15 operates, inductor L11, capacitor C11, and inductor L13 resonate and charge capacitor C11. This produces (Vs/2+VC11), and the potential VA of capacitor C11 goes to 3Vs/2+VC11 at time t2A. Therefore, at the rising edge of the sustain pulse, the current JL10 flow to inductor L10 rises even more sharply. As a result, the power supplied to scan electrodes SC1 to SCn at the rise of the sustain pulse increases, and the sustain pulse rises T2A1 faster than the first time the switching device Q15 operates. Operation after time t22A is the same as the operation after time t22 the first time the switching device Q15 operates. Though omitted here, the sustain pulse also falls sooner due to the operation of inductor L14.

The sustain pulse thus rises and falls faster with the sustain pulse generating circuit 501A shown in FIG. 10 than with the sustain pulse generating circuit 501 shown in FIG. 9.

### Embodiment 3

A third embodiment of the invention is described below focusing on the differences with the first embodiment. Other aspects of the configuration, operation, and effect of this embodiment are substantially the same as in the first embodiment, and further description thereof is thus omitted.

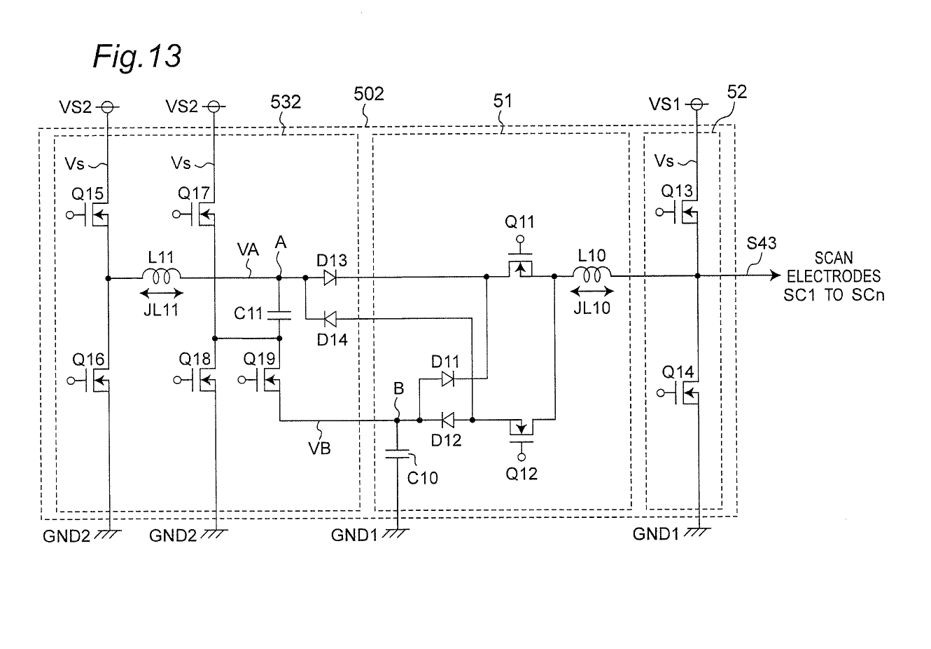

FIG. 13 is a circuit diagram of the sustain pulse generating circuit 502. The sustain pulse generating circuit 502 includes a power recovery circuit 51, clamping circuit 52, and auxiliary circuit 532. The configuration and operation of the power recovery circuit 51 and clamping circuit 52 are identical to the power recovery circuit 51 and clamping circuit 52 described in the first embodiment, and further description thereof is omitted.

The auxiliary circuit 532 includes a capacitor C11, switching device Q19, inductor L11, switching device Q15, switching device Q16, switching device Q17, switching device Q18, diode D13, and diode D14.

Capacitor C11 is an auxiliary capacitance connected in series to power recovery capacitor C10.

Switching device Q19 is inserted in series between capacitor C10 and capacitor C11, and is on when increasing or decreasing the potential VA of capacitor C11 by a so-called charge pump.

Inductor L11 is an auxiliary inductor that resonates with capacitor C11.

Switching device Q15 is a power supply side auxiliary switch that is on when boosting the potential VA of capacitor C11 by LC resonance.

Switching device Q16 is a reference potential side auxiliary switch that is on when lowering the potential VA of capacitor C11 by LC resonance.

Switching device Q17 is on when charge pumping capacitor C11 to the potential of power source VS2 (in this embodiment of the invention, potential Vs).

Switching device Q18 is on when charge pumping capacitor C11 to the reference potential (the ground potential in this embodiment of the invention).

Diode D13 is a diode that prevents the backflow of current flowing forward from capacitor C11 to inductor L10 at the sustain pulse rise.

Diode D14 is a diode that prevents the backflow of current flowing forward from inductor L10 to capacitor C11 at the sustain pulse fall.

One terminal of switching device Q19 is connected to one terminal of capacitor C10 (that is, node B), and the other terminal of switching device Q19 is connected to one terminal of capacitor C11. The other terminal of capacitor C11 (that is, node A) is connected to one terminal of inductor L11. One terminal of switching device Q15 is connected to the other terminal of inductor L11, and the other terminal of switching device Q15 is connected to VS2 and goes to potential Vs.

One terminal of switching device Q16 is connected to the node between inductor L11 and switching device Q15, and the other terminal of switching device Q16 is connected to ground terminal GND2 and goes to ground, that is, the reference potential.

One terminal of switching device Q17 is connected to the node between capacitor C11 and switching device Q19, and the other terminal of switching device Q17 is connected to source VS2 and set to potential Vs.

One terminal of switching device Q18 is connected to the connection node between capacitance C11, switching device Q19, and switching device Q17, and the other terminal of switching device Q18 is connected to ground terminal GND2 and goes to ground, that is, the reference potential.

The anode of diode D13 is connected to the node between capacitor C11 and inductor L11, and the cathode is connected to the connection node between switching device Q11 and diode D11.

The cathode of diode D14 is connected to the connection node between capacitor C11 and inductor L11, and the anode is connected to the node between switching device Q12 and diode D12. The auxiliary circuit 532 is thus configured.

Switching devices Q17, Q18, Q19 are also called simply switches.

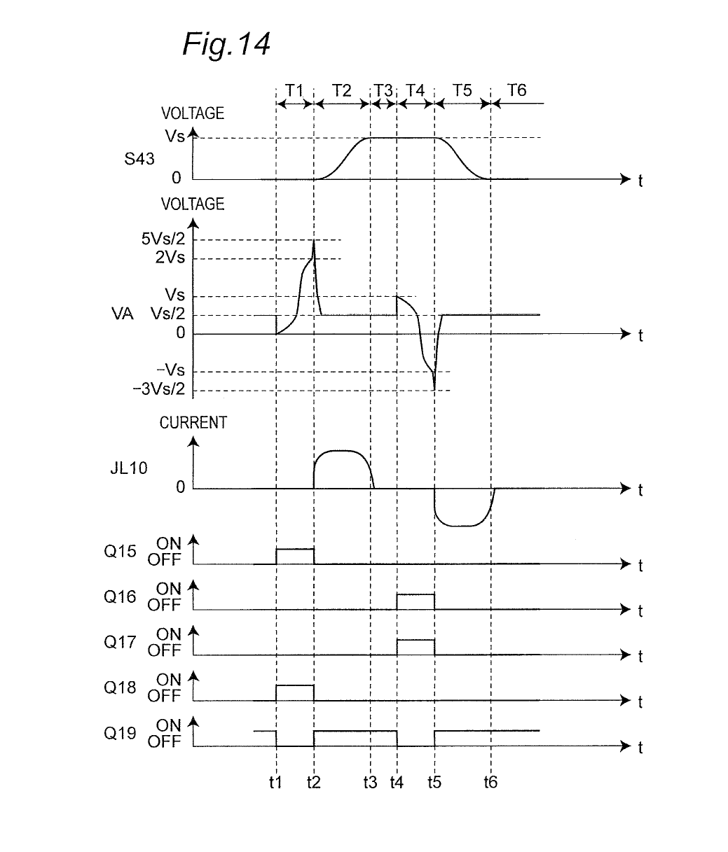

FIG. 14 is a timing chart for describing the operation of the sustain pulse generating circuit 502. FIG. 14 does not show the operation of switching device Q11, switching device Q12, switching device Q13, and switching device Q14, but the operation of these switching devices is the same as described in FIG. 7.

### (Period T1)

As shown in FIG. 14, immediately before power is supplied from capacitor C10 to scan electrodes SC1 to SCn, that is, at time t1 before switching device Q11 turns on, switching device Q19 turns off and switching device Q18 turns on. As a result, the potential VA of capacitor C11 is temporarily held to ground, that is, the reference potential.

At time t1, switching device Q15 turns on. As a result, current JL11 flows from power source VS2 through switching device Q15 and inductor L11 to capacitor C11, and the potential VA of capacitor C11 (the potential at node A in the figure) starts to rise. Because capacitor C11 is held by switching device Q18 to ground, the LC resonance of capacitor C11 and inductor L11 causes the potential VA of capacitor C11 to rise to approximately 2Vs, or twice voltage Vs, at time t2 after half the resonance period passes.

### (Period T2)

Next, at time t2, switching device Q15 and switching device Q18 turn off and switching device Q19 turns on. As a result, capacitor C11 and capacitor C10 are electrically connected, and the potential VA of capacitor C11 is charge pumped to 5Vs/2 by the addition of potential Vs/2 of capacitor C10 to voltage 2Vs at both ends of capacitor C11.

As described in FIG. 7, in period T2 power is supplied from capacitor C10 to scan electrodes SC1 to SCn by LC resonance. Because current flows to scan electrodes SC1 to SCn from capacitor C11, which is charged so that the potential at node A is potential 5Vs/2, the rise of current JL10 flowing to scan electrodes SC1 to SCn is sharper than when auxiliary circuit 532 is not used. In addition, because the potential VA of capacitor C11 can be made greater than in the first embodiment by voltage Vs in this third embodiment, the rise in the current JL10 that flows to scan electrodes SC1 to SCn can also be made steeper than in the first embodiment.

As in the first embodiment, the capacitance of capacitor C11 in this third embodiment is sufficiently lower than the capacitance of capacitor C10, and in this embodiment of the invention, the capacitance of capacitor C10 is 8 μF, and the capacitance of capacitor C11 is 0.02 μF.

### (Period T3)

The operation in period T3 is the same as described in FIG. 7, and further description thereof is omitted.

### (Period T4)

Next, immediately before power is recovered from scan electrodes SC1 to SCn to capacitor C10, that is, at time t4 before switching device Q12 turns on, switching device Q19 turns off and switching device Q17 turns on. As a result, the potential VA of capacitor C11 is temporarily held to the potential Vs of power source VS2.

At time t4 switching device Q16 turns on. As a result, current JL11 flows from capacitor C11 through inductor L11 and switching device Q16 to ground terminal GND2 at the reference potential, and the potential VA of capacitor C11 (the potential at node A in the figure) begins to fall. The capacitor C11 terminal on the switching device Q17 side is held to potential Vs by switching device Q17. As a result, the LC resonance of capacitor C11 and inductor L11 causes the potential VA of capacitor C11 to drop to near −Vs at time t5 after half the resonance period has passed.

### (Period T5)

Next, at time t5, switching device Q16 and switching device Q17 turn off and switching device Q19 turns on. As a result, capacitor C11 and capacitor C10 are electrically connected, and the potential VA of capacitor C11 is charged pumped to −3Vs/2 by the addition of potential Vs/2 of capacitor C10 to the voltage −2Vs at both ends of capacitor C11.

As described in FIG. 7, in period T5 power is recovered from scan electrodes SC1 to SCn to capacitor C10 by LC resonance. The flow of current from scan electrodes SC1 to SCn to capacitor C11, which is charged so that the potential at node A goes to −3Vs/2, makes the falling edge of the current JL10 flowing to scan electrodes SC1 to SCn steeper than in a configuration that does not use auxiliary circuit 532. In addition, because the potential VA of capacitor C11 can be reduced an additional voltage Vs compared with the first embodiment, the drop in the current JL10 flowing from scan electrodes SC1 to SCn can also be made sharper than in the first embodiment.

### (Period T6)

The operation in period T6 is the same as described in FIG. 7, and further description thereof is omitted.

As described above, this third embodiment of the invention adds switching device Q17, switching device Q18, and switching device Q19 to the configuration of the first embodiment, and charge pumps the potential VA of capacitor C11. As a result, the potential VA of capacitor C11 immediately before power is supplied from capacitor C10 to scan electrodes SC1 to SCn can be made higher than in the first embodiment, and can be made lower than in the first embodiment immediately before power is recovered from scan electrodes SC1 to SCn to capacitor C10. As a result, immediately after the power recovery circuit starts operating, the current flowing between the power recovery circuit and interelectrode capacitance Cp can be temporarily increased, and this increase can be made greater than in the first embodiment.

The configuration including switching device Q17, switching device Q18, and switching device Q19 is also called a charge pump circuit. The charge pump circuit charge pumps potential VA by switching the potential at one end of capacitor C11 (the node between capacitor C11 and switching device Q19).

### Embodiment 4

A fourth embodiment of the invention is described below focusing on the differences with the first embodiment. Other aspects of the configuration, operation, and effect of this embodiment are substantially the same as in the first embodiment, and further description thereof is thus omitted.

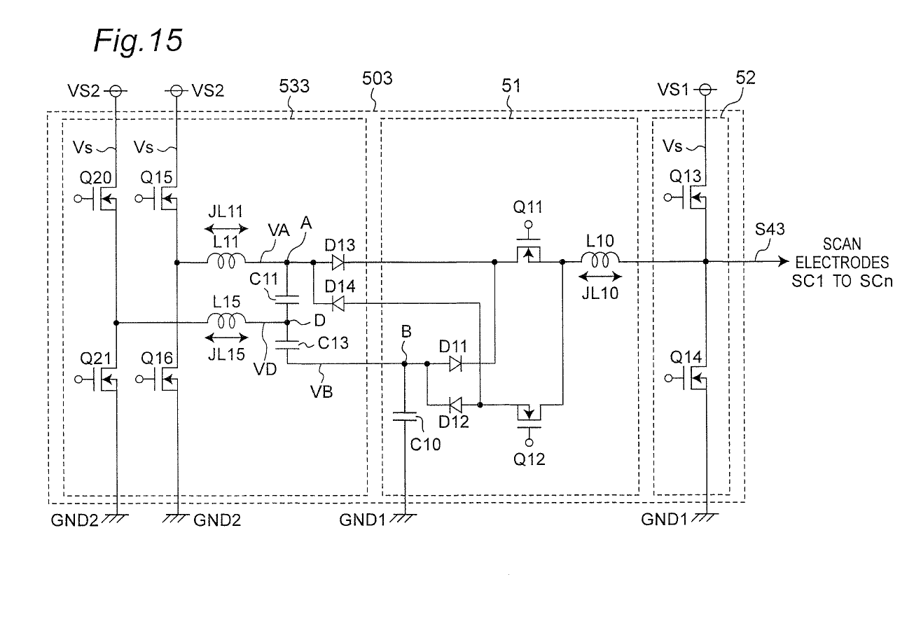

FIG. 15 is a circuit diagram of the sustain pulse generating circuit 503. The sustain pulse generating circuit 503 includes a power recovery circuit 51, clamping circuit 52, and auxiliary circuit 533. The configuration and operation of the power recovery circuit 51 and clamping circuit 52 are identical to the power recovery circuit 51 and clamping circuit 52 described in the first embodiment, and further description thereof is omitted.

The auxiliary circuit 533 includes capacitor C11, capacitor C13, inductor L11, inductor L15, switching device Q15, switching device Q16, switching device Q20, switching device Q21, diode D13, and diode D14.

Capacitor C11 and capacitor C13 are auxiliary capacitors connected in series to power recovery capacitor C10. Inductor L11 is an auxiliary inductor used for LC resonance with capacitor C11. Inductor L15 is an auxiliary inductor used for LC resonance with capacitor C13.

Switching device Q15 is a power supply side auxiliary switch that turns on when boosting the potential VA of capacitor C11 by LC resonance. Switching device Q16 is a reference potential side auxiliary switch that turns on when lowering the potential VA of capacitor C11 by LC resonance.

Switching device Q20 is a power supply side auxiliary switch that is on when boosting the potential VD of capacitor C13 at node D by LC resonance.

Switching device Q21 is a reference potential side auxiliary switch that turns on when lowering potential VD of capacitor C13 by LC resonance.

Diode D13 is a diode that prevents the backflow of current flowing forward from capacitor C11 to inductor L10 at the rising edge of the sustain pulse. Diode D14 is a diode that prevents the backflow of current flowing forward from inductor L10 to capacitor C11 at the falling edge of the sustain pulse.

So that capacitor C11, capacitor C13, and capacitor C10 are connected in series, one terminal of capacitor C13 is connected to one terminal of capacitor C10 (that is, node B), and the other terminal of capacitor C13 (that is, node D) is connected to one terminal of capacitor C11. The other terminal of capacitor C11 (node A) is connected to one terminal of inductor L11, the node between capacitor C11 and capacitor C13 is connected to one terminal of inductor L15.

One terminal of switching device Q15 is connected to the other terminal of inductor L11, and the other terminal of switching device Q15 is connected to power source VS2 and set to potential Vs.

One terminal of switching device Q20 is connected to the other terminal of inductor L15, and the other terminal of switching device Q20 is connected to power source VS2 and set to potential Vs.

One terminal of switching device Q16 is connected to the node between inductor L11 and switching device Q15, and the other terminal of switching device Q16 is connected to ground terminal GND2 and goes to ground, that is, the reference potential.

One terminal of switching device Q21 is connected to the connection node between inductor L15 and switching device Q20, and the other terminal of switching device Q21 is connected to ground terminal GND2 and goes to ground, that is, the reference potential.

The anode of diode D13 is connected to the node between capacitor C11 and inductor L11, and the cathode is connected to the connection node between switching device Q11 and diode D11.

The cathode of diode D14 is connected to the connection node between capacitor C11 and inductor L11, and the anode of diode D14 is connected to the node between switching device Q12 and diode D12. The auxiliary circuit 533 is thus configured.

In this fourth embodiment of the invention the capacitance of capacitor C11 and capacitor C13 is set sufficiently low compared with capacitor C10, and the capacitance of capacitor C11 is set lower than the capacitance of capacitor C13. In a preferred embodiment of the invention the capacitance ratio of capacitor C11 and capacitor C13 is set to 1:3. For example, capacitor C11 is set to 0.01 μF, capacitor C13 is set to 0.03 μF, and capacitor C10 is set to a comparatively high 8 μF.

Because switching device Q15, Q16 are off in the period when LC resonance is produced using inductor L15, the capacitance that produces LC resonance with inductor L15 is the combined capacitance of capacitor C13 and capacitor C10. However, in this embodiment of the invention, because the capacitance of capacitor C13 is sufficiently lower than capacitor C10, the combined capacitance of capacitor C13 and capacitor C10 can actually be made equal to capacitor C13.

In addition, the capacitance that produces LC resonance with inductor L11 is the combined capacitance of capacitor C11, capacitor C13, and capacitor C10. However, because the combined capacitance of capacitor C11 and capacitor C13 is sufficiently small compared with the capacitance of capacitor C10, the combined capacitance of capacitor C11, capacitor C13, and capacitor C10 can be treated as equal to the combined capacitance of capacitor C11 and capacitor C13. The inductance of inductor L11 and inductor L15 is preferably set accordingly.

Note, further, that the values shown here are for purposes of illustration only, and can obviously be set optimally according to the characteristics of the panel and the specifications of the plasma display device.

Capacitor C11, inductor L11, capacitor C13, and inductor L15 render an auxiliary storage circuit.

When on, switching device Q15 and switching device Q20 set the auxiliary storage circuit to potential Vs, and when on switching device Q16 and switching device Q21 set the auxiliary storage circuit to the reference potential.

The auxiliary storage circuit includes two secondary auxiliary storage circuits. Capacitor C11, capacitor C13, and inductor L11 render one auxiliary storage circuit, and capacitor C13 and inductor L15 render another secondary auxiliary storage circuit. Switching device Q15 sets the secondary auxiliary storage circuit including capacitor C11, capacitor C13, and inductor L11 to potential Vs when on, and switching device Q16 sets it to the reference potential when on. Switching device Q21 sets the other secondary auxiliary storage circuit including capacitor C13 and inductor L15 to potential Vs when on, and switching device Q21 sets it to the reference potential when on. Capacitor C11 and capacitor C13 render an auxiliary capacitance unit (an example of an auxiliary storage unit). Capacitor C11 and C13 are also called secondary auxiliary capacitance units. Inductor L11 and inductor L15 render an auxiliary inductance unit. Inductors L11 and L15 are also called secondary auxiliary inductance units.

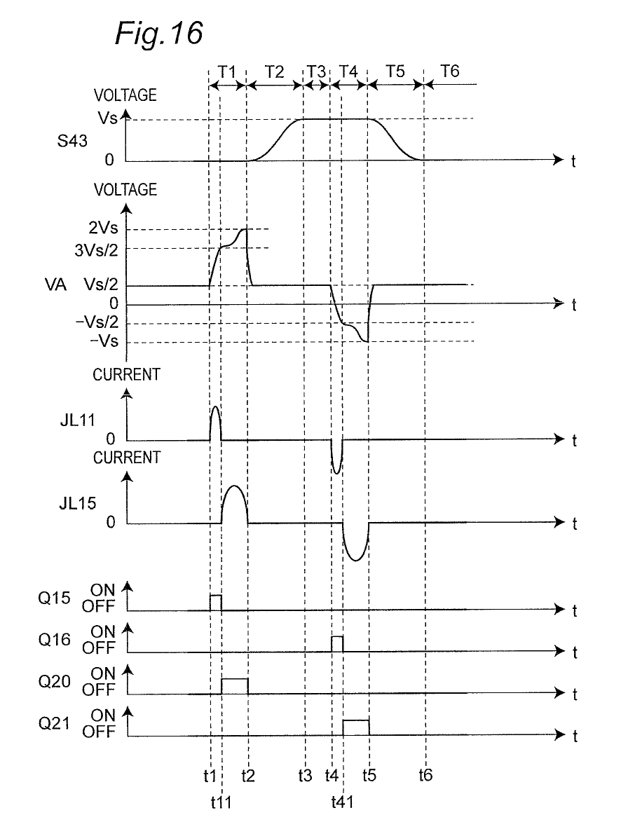

FIG. 16 is a timing chart describing the operation of the sustain pulse generating circuit 503. The operation of switching device Q11, switching device Q12, switching device Q13, and switching device Q14 is not shown in FIG. 16, but the operation of these switching devices is the same as described in FIG. 7.

### (Period T1)

As shown in FIG. 16, immediately before supplying power from capacitor C10 to scan electrodes SC1 to SCn, that is, at time t1 before switching device Q11 turns on, switching device Q15 turns on. As a result, current JL11 flows from power source VS2 through switching device Q15 and inductor L11 to capacitor C11, and the potential VA of capacitor C11 (the potential at node A in the figure) begins to rise. The potential VB of capacitor C10 is Vs/2, and capacitor C11, capacitor C13, and inductor L11 render a resonance circuit. As a result, at time t11 when half the resonance period has passed, the potential VA of capacitor C11 rises to approximately Vs/2+Vs, that is, 3Vs/2.

Because in this embodiment of the invention the capacitance ratio of capacitor C11 and capacitor C13 is set to 1:3 as described above, the voltage applied to capacitor C11 is 3Vs/4, and the voltage applied to capacitor C13 is Vs/4.

At time t11 switching device Q15 turns off and switching device Q20 turns on. As a result, current JL15 flows from power source VS2 through switching device Q20 and inductor L15 to capacitor C13, and the potential VD of capacitor C13 begins to rise. The potential VB of capacitor C10 is Vs/2, and the voltage of capacitor C13 is Vs/4. As a result, at time t2 after half the resonance period of capacitor C13 and inductor L15 has passed, the potential VD of capacitor C13 rises to Vs/2+Vs/4+Vs/2, that is, approximately 5Vs/4.

As a result, the potential VA of capacitor C11 (the potential at node A in the figure) is charge pumped by adding to the voltage 3Vs/4 applied to capacitor C11 the potential VD (=5Vs/4) of capacitor C13, and rises to 3Vs/4+5Vs/4, that is, approximately 2Vs.

### (Period T2)

Next, at time t2, switching device Q20 turns off. As described in FIG. 7, in period T2 power is supplied by LC resonance from capacitor C10 to scan electrodes SC1 to SCn. Then as a result of current flow to scan electrodes SC1 to SCn from capacitor C11, which is charged so that node A goes to potential 2Vs, the rise in current JL10 flowing to scan electrodes SC1 to SCn is sharper than when auxiliary circuit 533 is not used. In addition, because the potential VA of capacitor C11 can be increased voltage Vs/2 higher than in the first embodiment, the rise of current JL10 flowing to scan electrodes SC1 to SCn is steeper than in the first embodiment.

### (Period T3)

The operation in period T3 is the same as described in FIG. 7, and further description thereof is omitted.

### (Period T4)

At time t4 switching device Q16 turns on. As a result, current JL11 flows from capacitor C11 through inductor L11 and switching device Q16 to ground terminal GND2 at the reference potential, and the potential VA of capacitor C11 (the potential at node A in the figure) begins to drop. Because the potential VB of capacitor C10 is Vs/2, and capacitor C11, capacitor C13 and inductor L11 form a resonance circuit, at time t41 when a time of half the resonance period has passed, the potential VA of capacitor C11 drops to Vs/2−Vs, that is, approximately −Vs/2.

Because in this embodiment of the invention the capacitance ratio of capacitor C11 and capacitor C13 is set to 1:3 as described above, the voltage applied to capacitor C11 is −3Vs/4, and the voltage applied to capacitor C13 is −Vs/4.

At time t41 switching device Q16 turns off and switching device Q21 turns on. As a result, current JL15 flows from capacitor C13 through inductor L15 and switching device Q21 to ground terminal GND2 at the reference potential, and the potential VD of capacitor C13 begins to drop. The potential VB of capacitor C10 is Vs/2, and the voltage of capacitor C13 is −Vs/4. As a result, at time t2 after a time of half the resonance period of capacitor C13 and inductor L15 has passed, the potential VD of capacitor C13 falls to Vs/2−Vs/4−Vs/2, that is, approximately −Vs/4.

As a result, the potential VA of capacitor C11 (the potential at node A in the figure) is charge pumped, that is, the potential VD of capacitor C13 (=−Vs/4) is added to the voltage −3Vs/4 applied to capacitor C11, and falls to −3Vs/4−Vs/4, that is, approximately −Vs.

### (Period T5)

Next, at time t5, switching device Q21 turns off. As described in FIG. 7, in period T5 power is recovered by LC resonance from the scan electrodes SC1 to SCn to capacitor C10. Because current flows from scan electrodes SC1 to SCn to the capacitor C11 charged so that the potential at node A is −Vs, the drop in the current JL10 flowing to scan electrodes SC1 to SCn is steeper than when auxiliary circuit 533 is not used. In addition, because the potential VA of capacitor C11 can be reduced voltage −Vs/2 more than in the first embodiment, the fall of current JL10 flowing from the scan electrodes SC1 to SCn can also be made steeper than in the first embodiment.

As described above, the auxiliary capacitance of the first embodiment is rendered in this fourth embodiment of the invention by means of a plurality of capacitors (2 in this embodiment of the invention) connected in series. In addition, the same number of auxiliary inductors, power supply side auxiliary switches, and reference potential side auxiliary switches as the number of capacitors rendering the auxiliary capacitance are also provided. As a result, the potential VA of capacitor C11 can be set higher than in the first embodiment immediately before supplying power from the capacitor C10 to scan electrodes SC1 to SCn, and can be set lower than in the first embodiment immediately before recovering power from the scan electrodes SC1 to SCn to capacitor C10. As a result, immediately after the start of power recovery circuit operation, the temporary increase in the current flowing between the power recovery circuit and interelectrode capacitance Cp can be made greater than in the first embodiment.

With the configuration according to this embodiment of the invention, the potential VA of capacitor C11 can be increased (or decreased) more by increasing the number of serially connected capacitors.

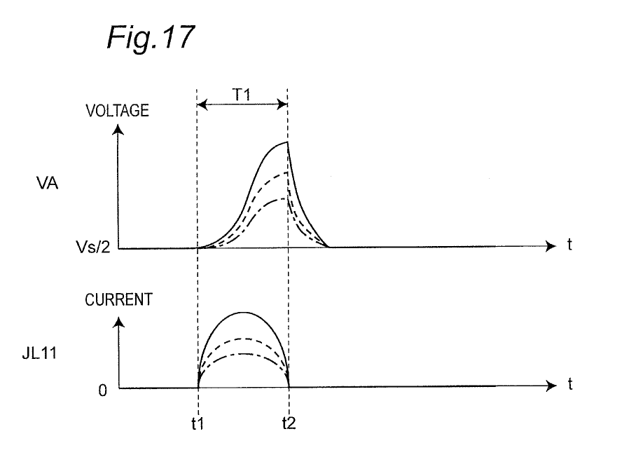

The foregoing embodiments describe configurations that use the potential Vs of the power source VS2 on the high voltage side as the supply potential of the auxiliary circuit, and use ground as the reference potential of the ground terminal GND2 on the low voltage side, but a configuration in which the potential Vs and reference potential are variable is also conceivable. FIG. 17 is a waveform diagram of another embodiment of the invention in which the supply potential of the auxiliary circuit is variable. For example, when charging power from power source VS2 to the auxiliary capacitor, the potential VA of the auxiliary capacitor can be increased as indicated by the solid line by increasing the potential Vs. Conversely, by lowering potential Vs, the potential VA of the auxiliary capacitor can be lowered as shown by the broken line and dot-dash line. Yet further, while not shown in the figure, the reference potential can be variably adjusted in the same way to the same effect.

Therefore, a configuration that controls the potential Vs (and/or the reference potential) of the auxiliary circuit power source VS2 according to the displayed image may be provided. More specifically, a configuration that increases potential Vs (decreases the reference potential) when the display image is bright, or when the on ratio, which is the ratio of discharge cells that emit to the total number of discharge cells, is high, and conversely decreases the power supply potential Vs (increases the reference potential) when the display image is dark, or the on ratio is low, is also conceivable. This configuration enables further improving display image quality.

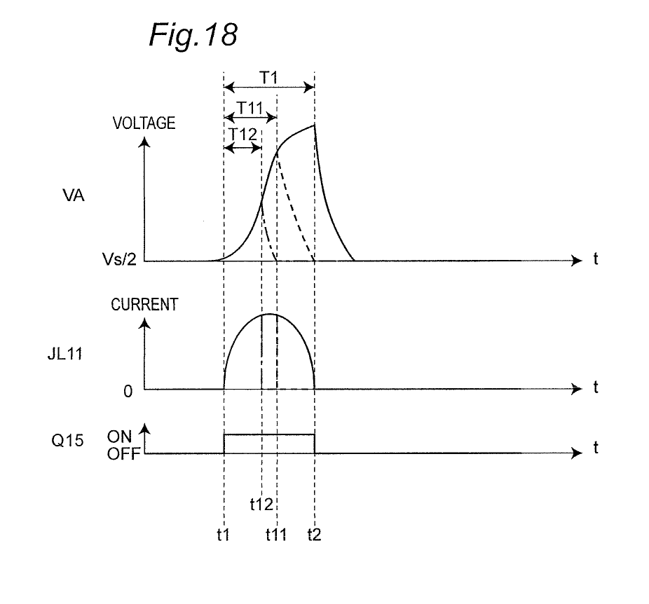

A configuration that, for example, varies the energize time (period T1 and period T4 in FIG. 7) of the power supply side auxiliary switch (switching device Q15) and reference potential side auxiliary switch (switching device Q16) of the auxiliary circuit is also conceivable. FIG. 18 is a waveform diagram of another embodiment of the invention in which the energize time of the power supply side auxiliary switch is variable.

For example, when charging power from the power source VS2 to the auxiliary capacitor, the voltage of the auxiliary capacitor can be increased as shown by the solid line by increasing the power supply side auxiliary switch energize time (period T1 in FIG. 18), and conversely by shortening the power supply side auxiliary switch energize time (period T11 and period T12 in FIG. 18), the voltage of the auxiliary capacitor can be decreased as shown by the broken line and dot-dash line. Furthermore, while not shown in the figure, this also applies to the operation of discharging power from the auxiliary capacitor to the reference potential, and the same effect can be achieved by making the reference potential side auxiliary switch energize time variable.

A configuration that controls the energize time of the power supply side auxiliary switch and reference potential side auxiliary switch of the auxiliary circuit according to the displayed image may therefore be provided. More specifically, a configuration that increases the power supply side auxiliary switch and reference potential side auxiliary switch energize time when the displayed image is bright or the on ratio is high, and conversely shortens the energize time when the displayed image is dark or the on ratio is low, is also conceivable. This configuration enables further improving display image quality.

Configurations that use the same inductor L10 in the power recovery circuit 51 during power recovery and power supply are described in the foregoing embodiments, but a configuration that uses two inductors instead of inductor L10, that is, an inductor L10a that is used when supplying power from power recovery capacitor C10 to scan electrodes SC1 to SCn, and an inductor L10b that is used when recovering power from scan electrodes SC1 to SCn to power recovery capacitor C10, is also conceivable. As a result, the resonance period can be set differently when recovering power from the display electrode pairs 24 and when supplying power to the display electrode pairs 24.

As described above, by using an auxiliary circuit at the rising and falling pulse edges of the sustain pulse, the amount of current flowing to the recovery inductor can be increased rapidly. As a result, a sustain pulse clamping period can be assured even when panel resolution is increased and the sustain pulse period is shortened, and the peak current flowing between the recovery inductor and interelectrode capacitance Cp can be reduced by increasing the resonance period of the recovery inductor and the interelectrode capacitance Cp. As a result, a stable sustain discharge can be produced by assuring a sufficient clamping period, and power consumption and EMI can be reduced by reducing the peak current, even in a high resolution panel.

It should be noted that the specific numeric values used in the foregoing embodiments of the invention were set based on tests using a 50-inch panel with 1080 display electrode pairs, and simply refer to an example of one preferred embodiment of the invention. The invention is not limited to these values, and the values may be optimized for the panel characteristics or the specifications of the plasma display device, for example. Note, further, that the foregoing values allow for deviation within the range achieving the effects described above.

The invention was conceived with consideration for the foregoing problems, and can be beneficially used to reduce power consumption, reduce EMI, and achieve a stable sustain discharge in a plasma display device and a drive method for a plasma display panel even when the panel is a high definition display panel.

The embodiments described above are examples of the present invention and, therefore, the scope of the present invention is not limited to those embodiments, but includes other embodiments and modifications and combinations of such embodiments that are apparent to the skilled person.

### INDUSTRIAL APPLICABILITY

The invention can be used in a capacitive load drive device, in a plasma display device that uses the capacitive load drive device, and in a drive method for a plasma display panel.

1-58. (canceled)

59. A capacitive load drive device comprising:
a sustain pulse generating circuit that applies a sustain pulse to a capacitive load and includes
a power recovery circuit that has a recovery inductor for a first LC resonance and a recovery capacitor for power recovery, recovers power stored in the capacitive load into the recovery capacitor when the sustain pulse falls by means of the first LC resonance of the capacitive load and the recovery inductor, and supplies the recovered power to the capacitive load for reuse when the sustain pulse rises,
a clamping circuit that clamps the capacitive load to the supply potential and the ground potential, and
an auxiliary circuit that has an auxiliary capacitor that is an auxiliary capacitor connected in series with the recovery capacitor and has lower capacitance than the recovery capacitor, and an auxiliary inductor that is used for second LC resonance;
the auxiliary circuit setting the potential of the auxiliary capacitor to a higher potential than the recovery capacitor immediately before the sustain pulse starts to rise, and to a lower potential than the recovery capacitor immediately before the sustain pulse starts to fall, by charging the auxiliary capacitor by means of the second LC resonance of the auxiliary capacitor and the auxiliary inductor, and
temporarily increasing the current flowing to the recovery inductor to greater than the current that flows only as a result of the first LC resonance by discharging the charged auxiliary capacitor immediately after the sustain pulse starts to rise and starts to fall.

60. A plasma display device having a sustain pulse generating circuit that alternately applies a sustain pulse during the sustain period of a subfield having an initialization period, an address period, and a sustain period to display electrode pairs of a plasma display panel that has a plurality of scan electrodes and sustain electrodes rendering the display electrode pairs, wherein:
the sustain pulse generating circuit comprises
a power recovery circuit that has a recovery inductor for a first LC resonance and a recovery capacitor for power recovery, recovers power stored in the interelectrode capacitance of the display electrode pairs into the recovery capacitor when the sustain pulse falls by means of the first LC resonance of the interelectrode capacitance and the recovery inductor, and supplies the recovered power to the display electrode pairs for reuse when the sustain pulse rises,
a clamping circuit that clamps the display electrode pairs to the supply potential and the ground potential, and
an auxiliary circuit that has an auxiliary capacitor that is an auxiliary capacitor connected in series with the recovery capacitor and has lower capacitance than the recovery capacitor, and an auxiliary inductor that is used for second LC resonance;
the auxiliary circuit setting the potential of the auxiliary capacitor to a higher potential than the recovery capacitor immediately before the sustain pulse starts to rise, and to a lower potential than the recovery capacitor immediately before the sustain pulse starts to fall, by charging the auxiliary capacitor by means of the second LC resonance of the auxiliary capacitor and the auxiliary inductor, and
temporarily increasing the current flowing to the recovery inductor to greater than the current that flows only as a result of the first LC resonance by discharging the charged auxiliary capacitor immediately after the sustain pulse starts to rise and starts to fall.

61. The plasma display device described in claim 60, wherein:
the auxiliary circuit includes
a power supply side auxiliary switch that has one terminal electrically connected to the supply potential and the other terminal electrically connected to the auxiliary inductor, and conducts when increasing the potential of the auxiliary capacitor,
a reference potential side auxiliary switch that has one terminal electrically connected to the reference potential and the other terminal electrically connected to the auxiliary inductor, and conducts when lowering the potential of the auxiliary capacitor,
a first diode that prevents backflow of current flowing forward from the auxiliary capacitor to the recovery inductor when the sustain pulse rises, and
a second diode that prevents backflow of current flowing forward from the recovery inductor to the auxiliary capacitor when the sustain pulse falls.

62. The plasma display device described in claim 60, wherein:
the auxiliary circuit sets the capacitance of the auxiliary capacitor and the inductance of the auxiliary inductor so that ½ the resonance period of the auxiliary capacitor and the auxiliary inductor is less than the period that the display electrode pairs are clamped to the supply potential and less than the period the display electrode pairs are clamped to the ground potential when the sustain pulse is produced.

63. The plasma display device described in claim 61, wherein:
the auxiliary circuit renders the auxiliary inductor by a first auxiliary inductor that is used when current flows from the supply potential side to the auxiliary capacitor, and a second auxiliary inductor that is used when current flows from the auxiliary capacitor to the reference potential side, and
is configured with the other terminal of the power supply side auxiliary switch electrically connected to the first auxiliary inductor, and the other terminal of the reference potential side auxiliary switch electrically connected to the second auxiliary inductor.

64. The plasma display device described in claim 63, wherein:
the auxiliary circuit renders the auxiliary capacitor by a power supply side auxiliary capacitor that is used when setting a higher potential than the recovery capacitor and a reference potential side auxiliary capacitor that is used when setting a lower potential than the recovery capacitor, and
uses the first auxiliary inductor for LC resonance with the power supply side auxiliary capacitor, and uses the second auxiliary inductor for LC resonance with the reference potential side auxiliary capacitor.

65. The plasma display device described in claim 64, wherein:
the auxiliary circuit connects a third auxiliary inductor separately from the first auxiliary inductor in series with the power supply side auxiliary capacitor, and
connects a fourth auxiliary inductor separately from the second auxiliary inductor in series with the reference potential side auxiliary capacitor.

66. The plasma display device described in claim 60, wherein:
in order to charge pump the auxiliary capacitor, the auxiliary circuit has a switching device inserted in series between the recovery capacitor and the auxiliary capacitor, and two switching devices disposed in series between the supply potential and the reference potential with an electrical connection point electrically connected to the auxiliary capacitor.

67. The plasma display device described in claim 60, wherein:
the auxiliary circuit has a plurality of capacitors connected in series rendering the auxiliary capacitor, and the same number of auxiliary inductors, power supply side auxiliary switches, and reference potential side auxiliary switches as the number of plural capacitors rendering the auxiliary capacitance.

68. A plasma display panel drive method that drives a plasma display device having a plurality of scan electrodes and sustain electrodes rendering the display electrode pairs
by using a power recovery circuit that has a recovery inductor for a first LC resonance and a recovery capacitor for power recovery, recovers power stored in the interelectrode capacitance of the display electrode pairs into the recovery capacitor when the sustain pulse falls by means of the first LC resonance of the interelectrode capacitance and the recovery inductor, and supplies the recovered power to the display electrode pairs for reuse when the sustain pulse rises, a clamping circuit that clamps the display electrode pairs to the supply potential and the ground potential, and an auxiliary circuit that has an auxiliary capacitor that is an auxiliary capacitor connected in series with the recovery capacitor and has lower capacitance than the recovery capacitor, and an auxiliary inductor that is used for second LC resonance
to alternately apply a sustain pulse to the display electrode pairs during the sustain period of a subfield having an initialization period, an address period, and a sustain period,
the drive comprising steps of:
setting the potential of the auxiliary capacitor to a higher potential than the recovery capacitor immediately before the sustain pulse starts to rise, and to a lower potential than the recovery capacitor immediately before the sustain pulse starts to fall, by charging the auxiliary capacitor by means of the second LC resonance of the auxiliary capacitor and the auxiliary inductor; and
temporarily increasing the current flowing to the recovery inductor to greater than the current that flows only as a result of the first LC resonance by discharging the charged auxiliary capacitor immediately after the sustain pulse starts to rise and starts to fall.

69. The drive method for a plasma display panel described in claim 68, wherein:
a power supply side auxiliary switch having one terminal electrically connected to a supply potential and the other terminal electrically connected to the auxiliary inductor, and a reference potential side auxiliary switch having one terminal electrically connected to a reference potential and the other terminal electrically connected to the auxiliary inductor, are disposed to the auxiliary circuit; and
the drive method energizes the power supply side auxiliary switch when increasing the potential of the auxiliary capacitor, and energizes the reference potential side auxiliary switch when lowering the potential of the auxiliary capacitor.

70. The drive method for a plasma display panel described in claim 69, wherein:
the time that the power supply side auxiliary switch is energized when increasing the potential of the auxiliary capacitor, and the time that the reference potential side auxiliary switch is energized when lowering the potential of the auxiliary capacitor, are controlled according to the display image.

71. A capacitive load drive device comprising:
a sustain pulse generating circuit that applies a sustain pulse to a capacitive load and includes
a power recovery circuit that has a recovery inductor for a first LC resonance, a recovery capacitor for power recovery, a power recovery path and a power supply path, recovers power stored in the capacitive load into the recovery capacitor through the power recovery path when the sustain pulse falls by means of the first LC resonance of the capacitive load and the recovery inductor, and supplies the recovered power through the power supply path to the capacitive load for reuse when the sustain pulse rises, and
an auxiliary circuit that has an auxiliary capacitor that is an auxiliary capacitor connected in series with the recovery capacitor and has lower capacitance than the recovery capacitor, an auxiliary inductor that is used for second LC resonance, a first charging path that charges the auxiliary capacitor in a first direction, and a second charging path that charges the auxiliary capacitor in a second direction;
the auxiliary circuit setting the potential of the auxiliary capacitor to a higher potential than the recovery capacitor by setting the auxiliary capacitor to charge in the first direction immediately before the sustain pulse starts to rise, and setting the potential of the auxiliary capacitor to a lower potential than the recovery capacitor by setting the auxiliary capacitor to charge in a second direction immediately before the sustain pulse starts to fall, based on the second LC resonance of the auxiliary capacitor and the auxiliary inductor, and
temporarily increasing the current flowing to the recovery inductor to greater than the current that flows only as a result of the first LC resonance by discharging the charged auxiliary capacitor immediately after the sustain pulse starts to rise and starts to fall.

72. A capacitive load drive device that applies a sustain pulse to a capacitive load and drives a capacitive load using primary power and auxiliary power, comprising:
a primary capacitance unit that can store and discharge the primary power;
an auxiliary storage unit that is a storage unit with lower capacitance than the primary capacitance unit and can store and discharge auxiliary power;
a primary inductance unit that produces a first LC resonance with the capacitive load;
a recovery path representing a path for recovering the primary power from the capacitive load through the primary inductance unit to the primary capacitance unit based on the first LC resonance when the sustain pulse falls;
a supply path representing a path for supplying the recovered primary power from the primary capacitance unit through the primary inductance unit to the capacitive load based on the first LC resonance when the sustain pulse rises;
a recovery charge path that includes the auxiliary storage unit and represents a path for charging the auxiliary power to the auxiliary storage unit in a direction strengthening the primary power recovery operation immediately before the sustain pulse starts to fall;
a recovery discharge path representing a path for discharging the auxiliary power charged to the auxiliary storage unit from the primary inductance unit to the auxiliary storage unit, and accelerating the primary power recovery operation, immediately after the sustain pulse starts to fall;
a supply charge path that includes the auxiliary storage unit, and represents a path for charging the auxiliary power to the auxiliary storage unit in a direction strengthening the primary power supply operation immediately before the sustain pulse starts to rise; and
a supply discharge path representing a path for discharging the auxiliary power charged to the auxiliary storage unit from the auxiliary storage unit to the primary inductance unit, and accelerating the primary power supply operation, immediately after the sustain pulse starts to rise;
wherein the recovery path shares at least part of the recovery discharge path, and
the supply path shares at least part of the supply discharge path.

73. The capacitive load drive device described in claim 72, further comprising:
a sustain circuit that can supply at least part of the primary power to the capacitive load, and can hold a specific electrode of the capacitive load to a primary potential and reference potential.

74. The capacitive load drive device described in claim 73, wherein:
the recovery path represents a path for recovering the primary power while the sustain potential held in the sustain circuit changes from the primary potential to the reference potential; and
the supply path represents a path for supplying the primary power while the sustain potential changes from the reference potential to the primary potential.

75. The capacitive load drive device described in claim 72, wherein:
the auxiliary storage unit is an auxiliary capacitance unit with capacitance.
the auxiliary capacitance unit includes a first secondary auxiliary capacitance unit and second secondary auxiliary capacitance unit.

76. The capacitive load drive device described in claim 72, wherein:
the recovery path includes a switch between the primary inductance unit and the primary capacitance unit.

77. The capacitive load drive device described in claim 72, wherein:
the supply path includes a switch between the primary capacitance unit and the primary inductance unit.

78. The capacitive load drive device described in claim 72, further comprising:
an auxiliary inductance unit that produces a second LC resonance with the auxiliary storage unit.

79. The capacitive load drive device described in claim 78, wherein:
the recovery charge path represents a path for charging the auxiliary power from one end of the primary capacitance unit through the auxiliary storage unit and the auxiliary inductance unit to the other end of the primary capacitance unit based on the second LC resonance.

80. The capacitive load drive device described in claim 78, wherein:
the supply charge path represents a path for charging the auxiliary power based on the second LC resonance from an auxiliary power supply that supplies the auxiliary power through the auxiliary inductance unit to the auxiliary storage unit.

81. A capacitive load drive device that drives a capacitive load using a first power source and a second power source, comprising:
a sustain circuit that supplies primary power from the first power source to a capacitive load, and holds a specific electrode of the capacitive load to a primary potential and reference potential;
a power feedback circuit that includes a primary capacitance unit for temporarily storing primary power, recovers primary power from the capacitive load to the primary capacitance unit while the sustain potential held in the sustain circuit undergoes a first change from a primary potential to a reference potential, and supplies the recovered primary power from the primary capacitance unit to the capacitive load while the sustain potential undergoes a second change from the reference potential to the primary potential; and
an auxiliary circuit that includes an auxiliary capacitance unit that is an auxiliary capacitance unit with lower capacitance than the primary capacitance unit and temporarily stores auxiliary power, sets the auxiliary capacitance unit to a charge state using auxiliary power from the power feedback circuit immediately before the first change starts, and sets the auxiliary capacitance unit to a charge state using auxiliary power from the second power source immediately before the second change starts;
wherein the power feedback circuit accelerates the primary power recovery operation and supply operation by discharging auxiliary power from the auxiliary capacitance unit immediately after the first change and the second change start.

82. The capacitive load drive device described in claim 81, wherein:
one end of the auxiliary capacitance unit is connected to one end of the primary capacitance unit.

83. The capacitive load drive device described in claim 82, wherein:
the auxiliary circuit sets the potential of the other end of the auxiliary capacitance unit lower than the potential of one end of the primary capacitance unit immediately before the first change starts, and sets the potential of the other end of the auxiliary capacitance unit greater than the potential of one end of the primary capacitance unit immediately before the second change starts.

84. The capacitive load drive device described in claim 82, wherein:
the auxiliary circuit includes an auxiliary inductance unit connected to the other end of the auxiliary capacitance unit; and
the auxiliary inductance unit resonates with the auxiliary capacitance unit.

85. The capacitive load drive device described in claim 84, wherein:
the auxiliary circuit sets the capacitance of the auxiliary capacitance unit and the inductance of the auxiliary inductance unit so that half the resonance period of the auxiliary capacitance unit and the auxiliary inductance unit is shorter than the period that the sustain potential is held.

86. The capacitive load drive device described in claim 82, wherein:
the auxiliary circuit includes a first diode connected in a forward direction from the other end of the auxiliary capacitance unit to the power feedback circuit, and
a second diode connected in a forward direction from the power feedback circuit to the other end of the auxiliary capacitance unit.

87. The capacitive load drive device described in claim 82, wherein:
the auxiliary circuit includes a charge pump circuit connected to one end of the primary capacitance unit and one end of the auxiliary capacitance unit;
the charge pump circuit charge pumping by switching the potential of one end of the auxiliary capacitance unit.

88. The capacitive load drive device described in claim 81, wherein:
the auxiliary circuit includes
an auxiliary storage circuit that temporarily stores power, and
a switch unit that is connected to the auxiliary storage circuit;
the switch unit connecting the auxiliary storage circuit to the second power source, and setting the auxiliary storage circuit to the auxiliary potential.

89. The capacitive load drive device described in claim 88, wherein:
the auxiliary storage circuit includes an auxiliary capacitance unit.

90. The capacitive load drive device described in claim 88, wherein:
the switch unit includes
a first switch that sets the auxiliary storage circuit to an auxiliary potential when conductive, and
a second switch that sets the auxiliary storage circuit to a reference potential when conductive.

91. The capacitive load drive device described in claim 88, wherein:
the auxiliary storage circuit includes a first secondary auxiliary storage circuit and a second secondary auxiliary storage circuit.

92. The capacitive load drive device described in claim 91, wherein:
the first secondary auxiliary storage circuit includes a first secondary auxiliary capacitance unit; and
the second secondary auxiliary storage circuit includes a second secondary auxiliary capacitance unit.

93. The capacitive load drive device described in claim 92, wherein:
the switch unit includes a first switch that sets the first secondary auxiliary storage circuit to an auxiliary potential when conductive; and
a second switch that sets the second secondary auxiliary storage circuit to a reference potential when conductive.

94. The capacitive load drive device described in claim 91, wherein:
the first secondary auxiliary storage circuit includes a first auxiliary capacitance unit and second auxiliary capacitance unit; and
the second secondary auxiliary storage circuit includes a second secondary auxiliary capacitance unit.

95. The capacitive load drive device described in claim 88, wherein:
the switch unit includes a first switch that when conductive sets the first secondary auxiliary storage circuit to an auxiliary potential or reference potential; and
a second switch that when conductive sets the second secondary auxiliary storage circuit to an auxiliary potential or reference potential.

96. The capacitive load drive device described in claim 88, wherein:
the auxiliary circuit changes the auxiliary potential or reference potential according to the display image.

97. The capacitive load drive device described in claim 88, wherein:
the switch unit varies the time set to the auxiliary potential or reference potential according to the display image.

98. A plasma display device that uses the capacitive load drive device described in claim 72.

99. A plasma display device that uses the capacitive load drive device described in claim 81.

100. A plasma display panel drive method that drives a capacitive load using a first power source and a second power source, comprising:
a step of supplying primary power from the first power source to a capacitive load, and holding a specific electrode of the capacitive load to a primary potential and reference potential;
step of using a primary capacitance unit that temporarily stores primary power to recover primary power from the capacitive load to the primary capacitance unit while the sustain potential held in the sustain circuit undergoes a first change from a primary potential to a reference potential, and supply the recovered primary power from the primary capacitance unit to the capacitive load while the sustain potential undergoes a second change from the reference potential to the primary potential; and
a step of using an auxiliary capacitance unit that is an auxiliary capacitance unit with lower capacitance than the primary capacitance unit and temporarily stores auxiliary power to set the auxiliary capacitance unit to a charge state using auxiliary power from the primary capacitance unit immediately before the first change starts, and set the auxiliary capacitance unit to a charge state using auxiliary power from the second power source immediately before the second change starts;
wherein the recovery and supply step accelerates the primary power recovery operation and supply operation by discharging auxiliary power from the auxiliary capacitance unit immediately after the first change and the second change start.

101. The plasma display panel drive method described in claim 100, wherein:
the step of charging the auxiliary capacitance unit sets the potential of the auxiliary capacitance unit lower than the potential of the primary capacitance unit immediately before the first change starts, and sets the potential of the auxiliary capacitance unit greater than the potential of the primary capacitance unit immediately before the second change starts.

102. The plasma display panel drive method described in claim 100, wherein:
the step of charging the auxiliary capacitance unit sets to an auxiliary potential from the second power source.
